(19) United States
(12) Patent Application Publication
(10) Pub. No.: US 2024/0074142 A1
(43) Pub. Date: Feb. 29, 2024

(54) MICROELECTRONIC DEVICES, RELATED MEMORY DEVICES, ELECTRONIC SYSTEMS, AND METHODS

(71) Applicant: Micron Technology, Inc., Boise, ID (US)

(72) Inventor: Fatma Arzum Simsek-Ege, Boise, ID (US)

(21) Appl. No.: 17/898,233

(22) Filed: Aug. 29, 2022

(51) Int. Cl. H01L 27/108

(52) U.S. Cl. CPC H01L 27/10805; H01L 27/10885

(57) ABSTRACT

A microelectronic device comprises a vertical stack of memory cells. Each vertical stack of memory cells comprises a vertical stack of access devices, a vertical stack of capacitors horizontally neighboring the vertical stack of access devices, and a conductive pillar structure in electrical communication with the vertical stack of access devices. The microelectronic device further comprises first global digit lines vertically neighboring the vertical stacks of memory cells, and second global digit lines horizontally interleaved with the first global digit lines in a horizontal direction, the second global digit lines vertically spaced from the vertical stacks of memory cells a greater distance than the first global digit lines. Related memory devices, electronic systems, and methods are also described.

### TECHNICAL FIELD

The disclosure, in various embodiments, relates generally to the field of microelectronic device design and fabrication. More specifically, the disclosure relates to methods of microelectronic devices including vertically spaced global digit lines, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the size of the memory cells has decreased, the density and complexity of the memory array have increased. With the increased density of memory cells within the memory array, the density of the conductive interconnect structures configured to facilitate operation of the memory cells has also increased. For example, the spacing between neighboring conductive interconnect structures has decreased with the increased density of memory cells of the memory array. However, the increased density of the conductive interconnect structures presents difficulties in adequately forming conductive interconnect structures in electrical communication with the memory cells.

### BRIEF DESCRIPTION OF THE DRAWINGS

FIG. 1A through FIG. 1R are simplified partial top-down views (FIG. 1A and FIG. 1Q), simplified partial cross-sectional views (FIG. 1B through FIG. 1D and FIG. 1F through FIG. 1P), and simplified partial perspective views (FIG. 1E and FIG. 1R) illustrating a method of forming a first microelectronic device structure, in accordance with embodiments of the disclosure;

FIG. 2A through FIG. 2C are simplified partial cross-sectional views of a microelectronic device formed from the first microelectronic device structure and a second microelectronic device structure, in accordance with embodiments of the disclosure; and

FIG. 3 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessary limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, “semiconductor material” or “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

According to embodiments described herein, a microelectronic device includes a microelectronic device structure comprising a vertical stack of memory cells, each vertical stack of memory cells comprising a vertical stack of access devices operably coupled to a vertical stack of storage devices (e.g., capacitors). Conductive pillar structures (also referred to herein as “local digit lines”) are in electrical communication with the access devices of the vertical stacks of access devices to selectively couple to storage devices of the vertical stack of storage devices. The conductive pillar structures are individually in electrical communication with a global digit line by means of a global digit line contact structure. The global digit lines include high global digit lines located a greater distance from the vertically uppermost level of the memory cells of the vertical stack of memory cells than low global digit lines. In some such embodiments, the high global digit lines are located farther from a vertically uppermost portion of the conductive pillar structures than the low global digit lines. In some embodiments, every other one of the global digit lines in a first horizontal direction (e.g., in the direction of conductive structures, such as word lines) is a high global digit line and the other global digit lines in the first direction are the low global digit lines. Alternating the high global digit lines with the low global digit lines facilitates reducing the capacitive coupling between horizontally neighboring global digit lines. In addition, the vertically alternating high global digit lines and low global digit lines provides a larger process margin (e.g., an increased area) for forming the global digit lines and space for forming relatively larger global digit lines for the same density of memory cells. The larger global digit lines exhibit a lower resistance compared to relatively smaller global digit lines. Further, the alternating high global digit lines and the low global digit lines facilitates a reduction in the resistance-capacitance (RC) product (also referred as the “RC delay”), which improves the operation of sense amplifiers operably coupled to the global digit lines. In addition, forming the microelectronic device structure to include the vertically alternating high global digit lines and the low global digit lines allows the global digit lines to be operably coupled to a greater quantity of the conductive pillar structures, and decreases a quantity of sense amplifiers of the microelectronic device.

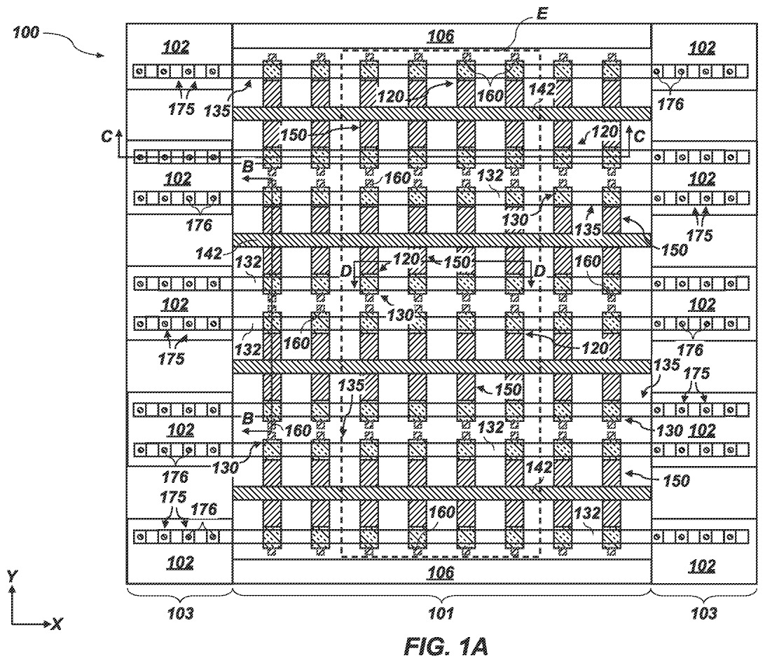

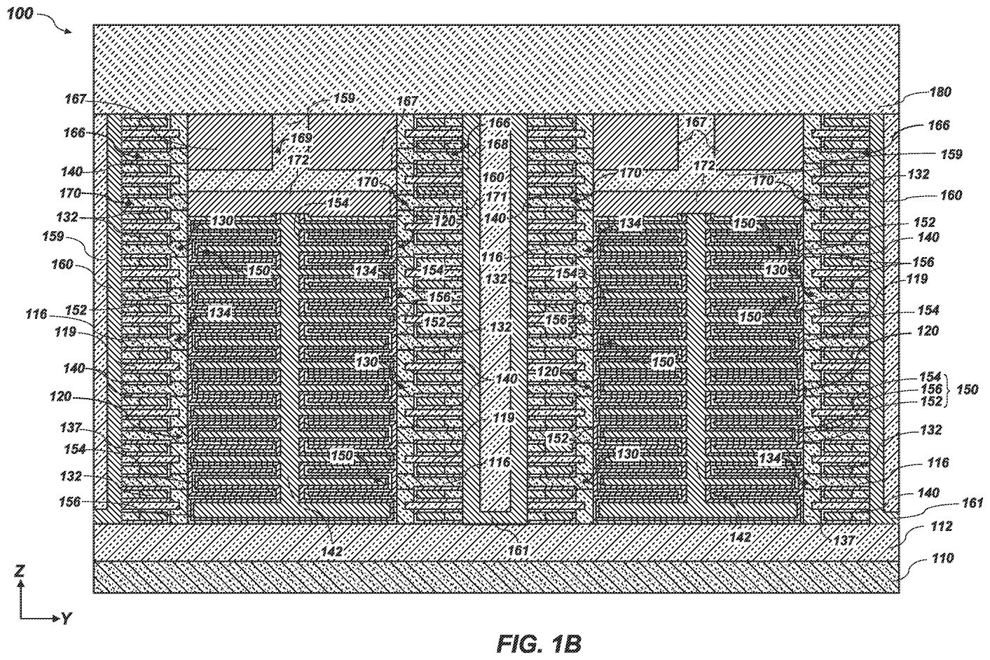

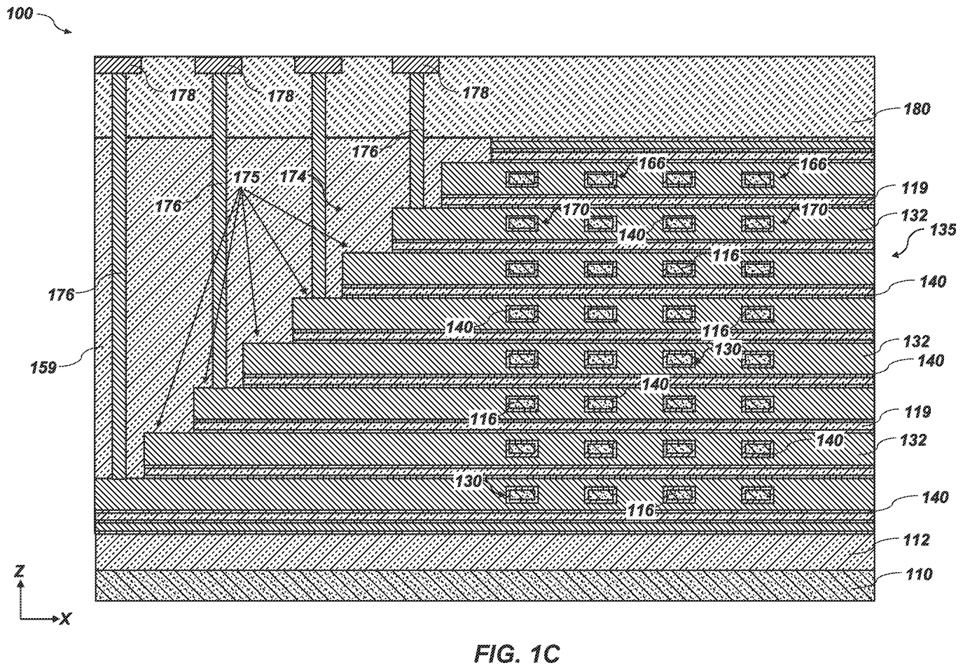

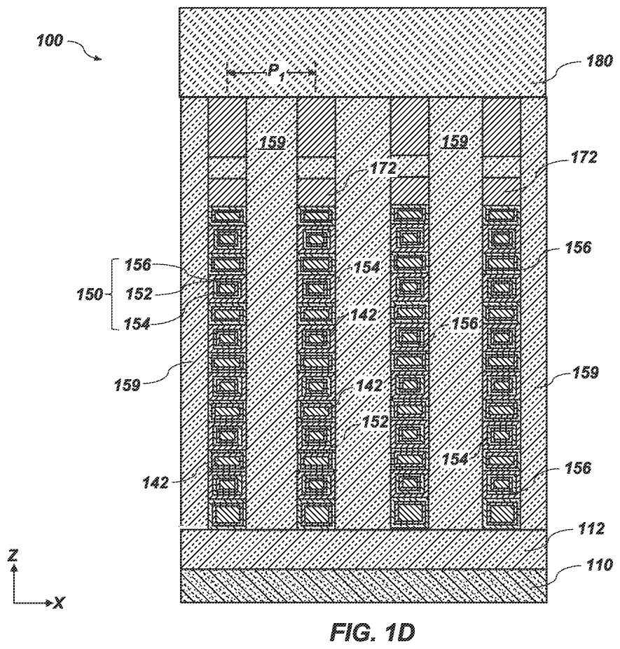

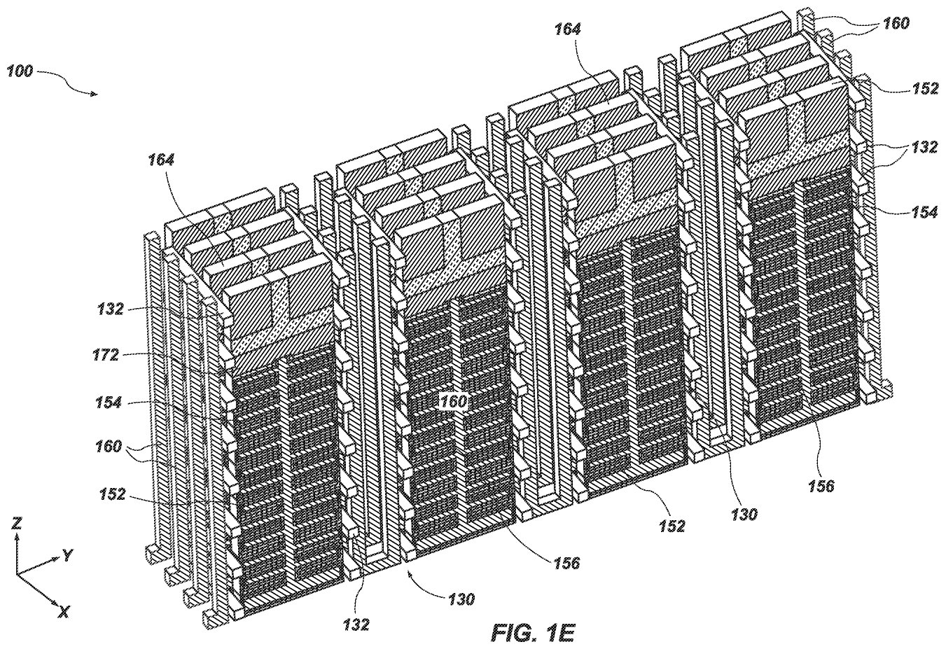

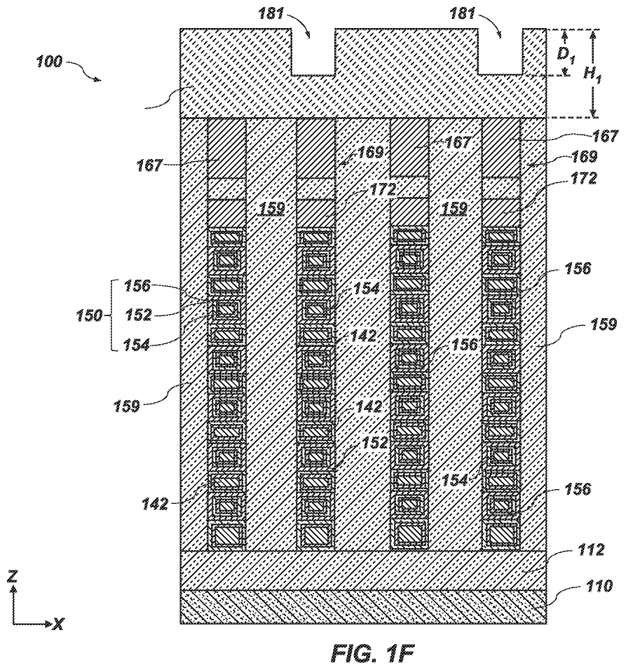

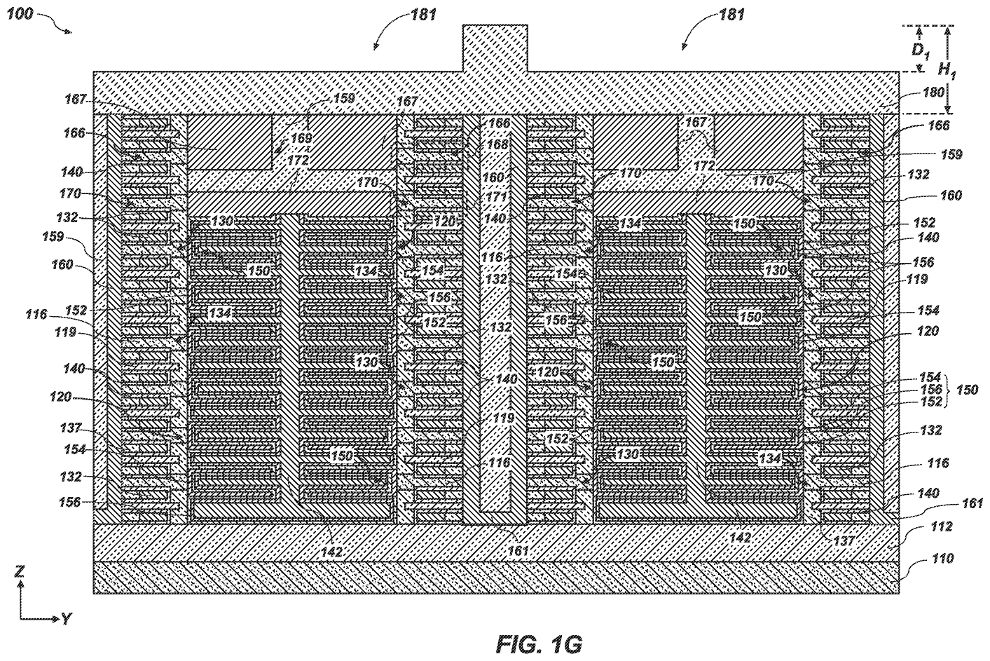

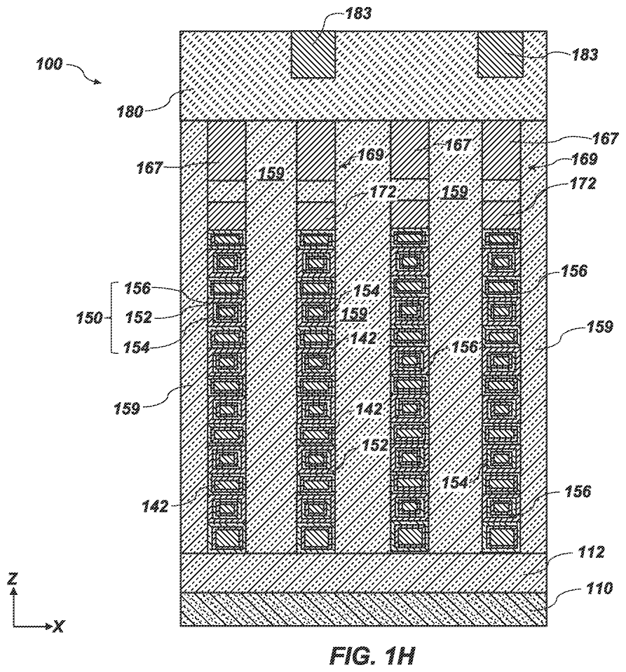

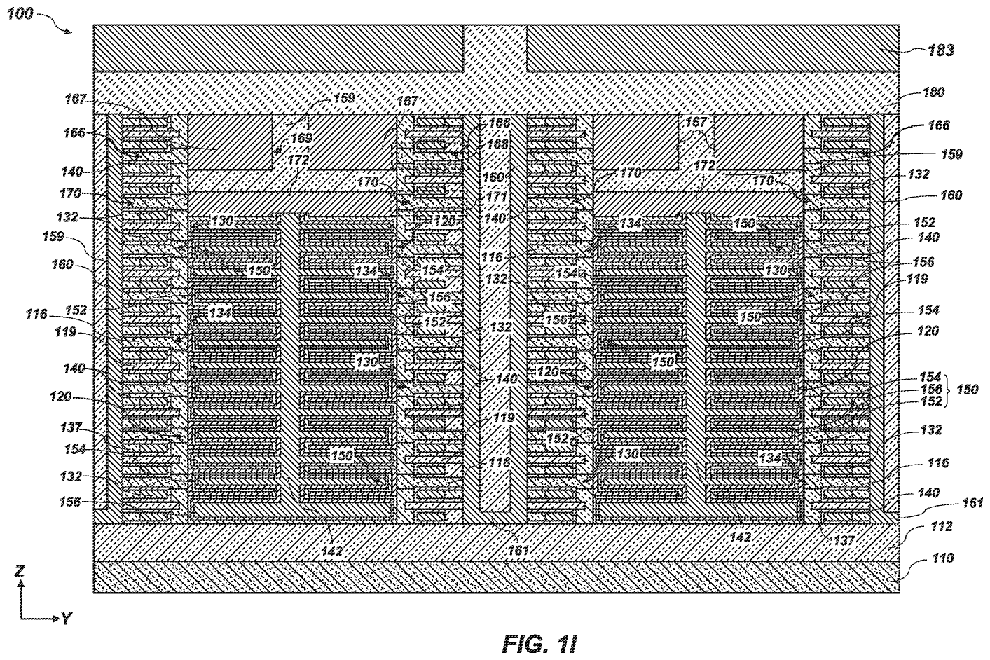

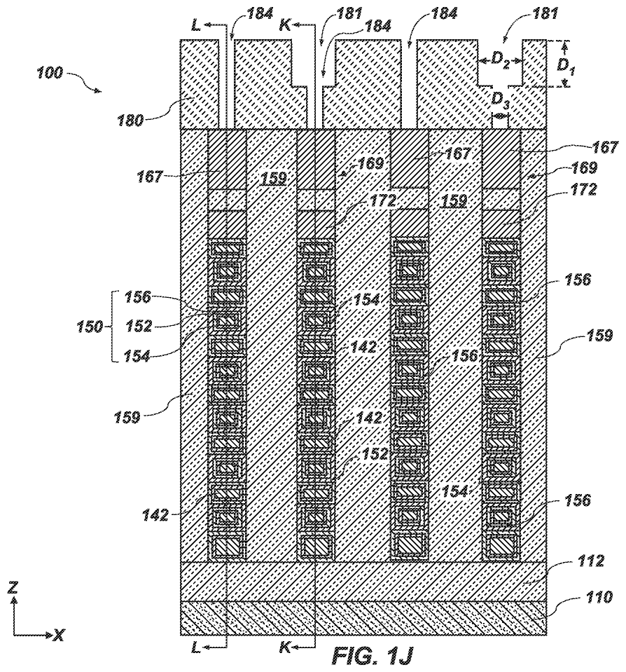

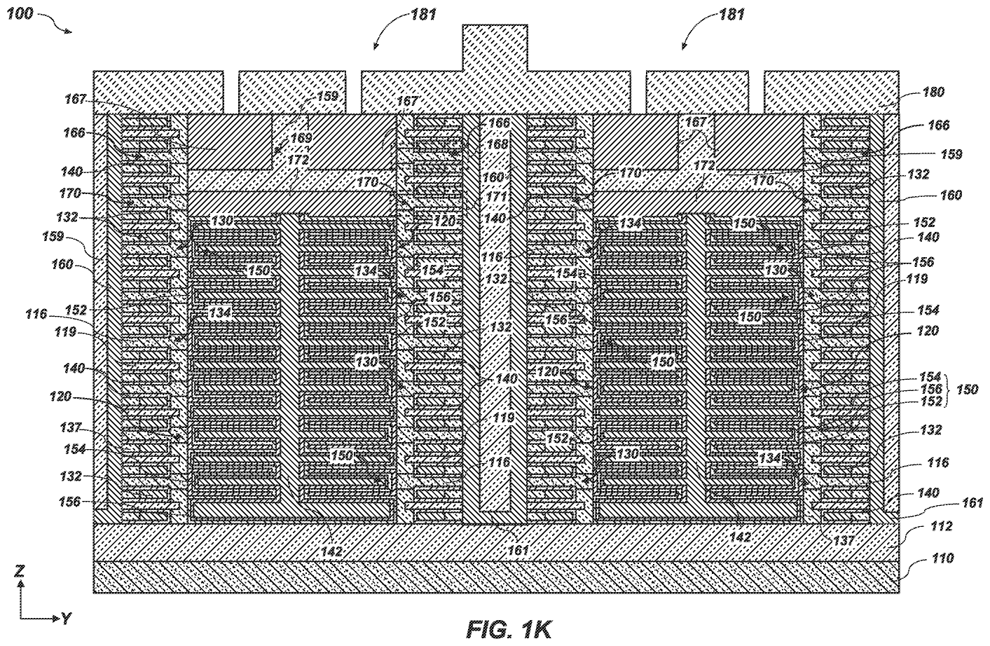

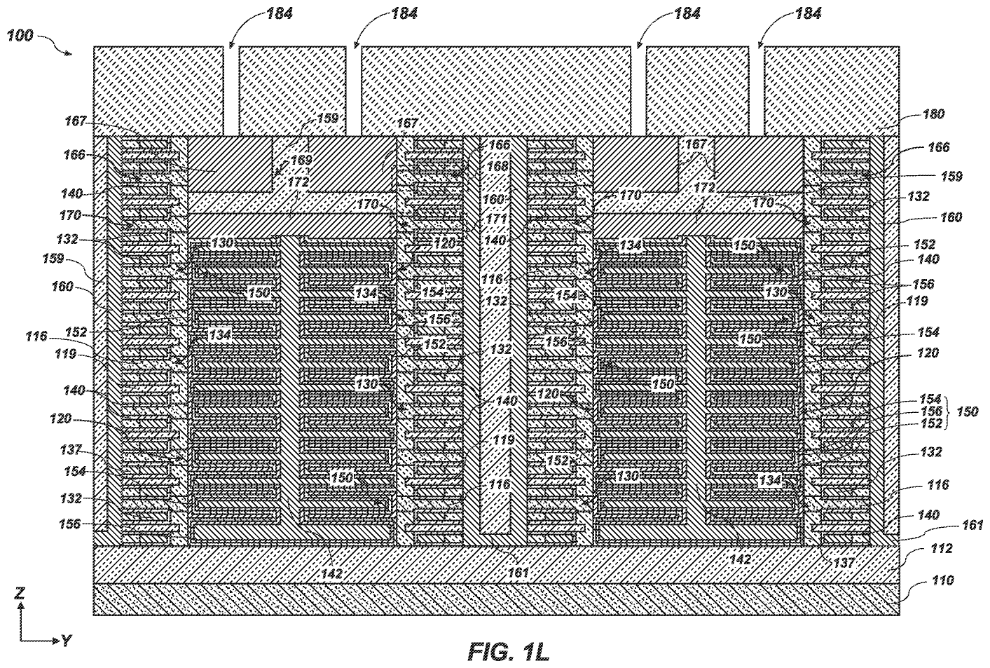

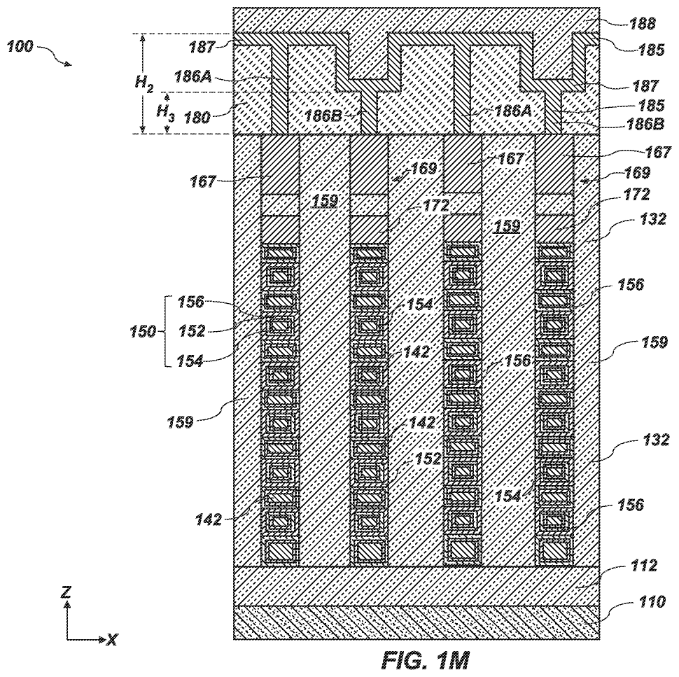

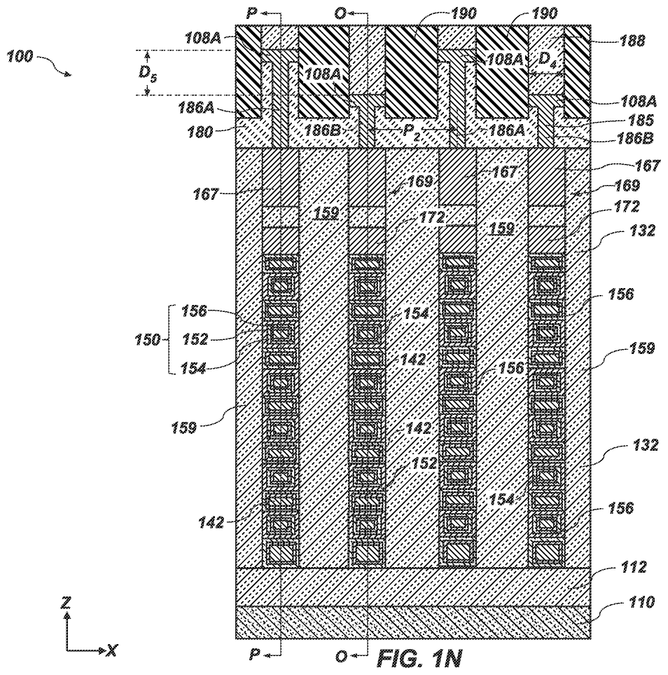

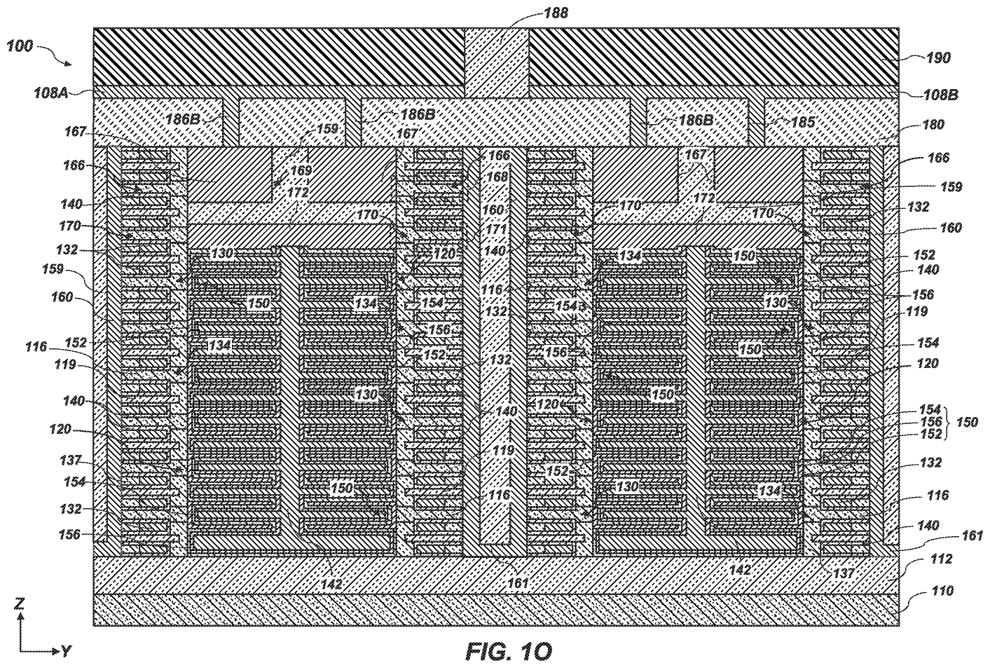

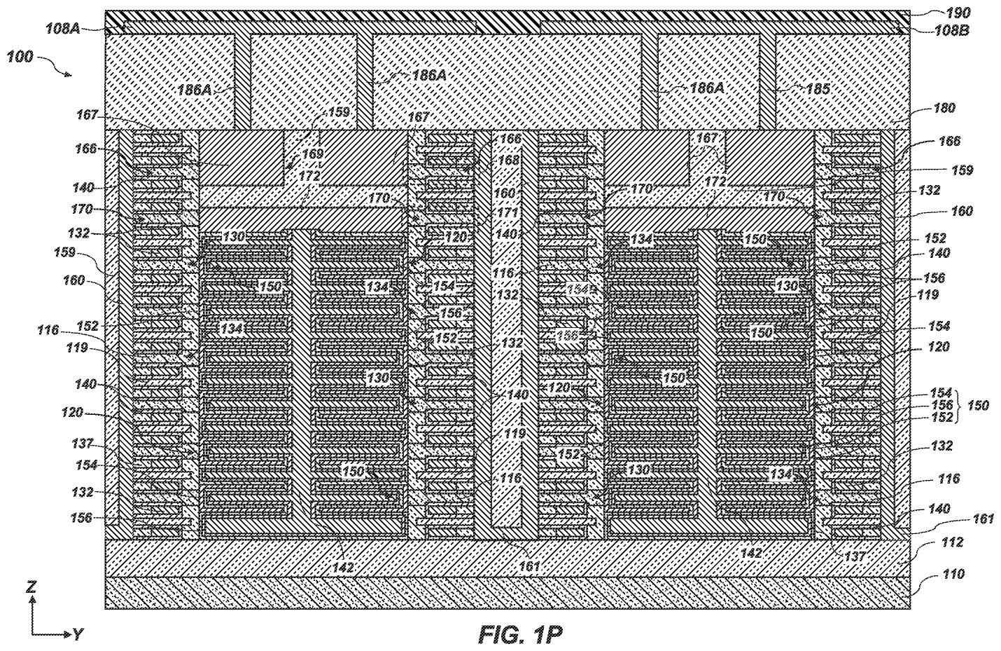

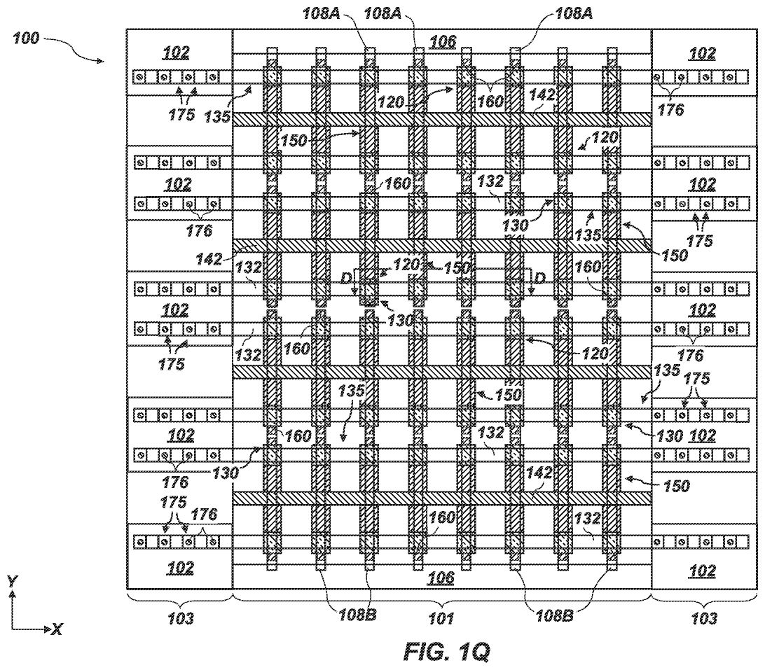

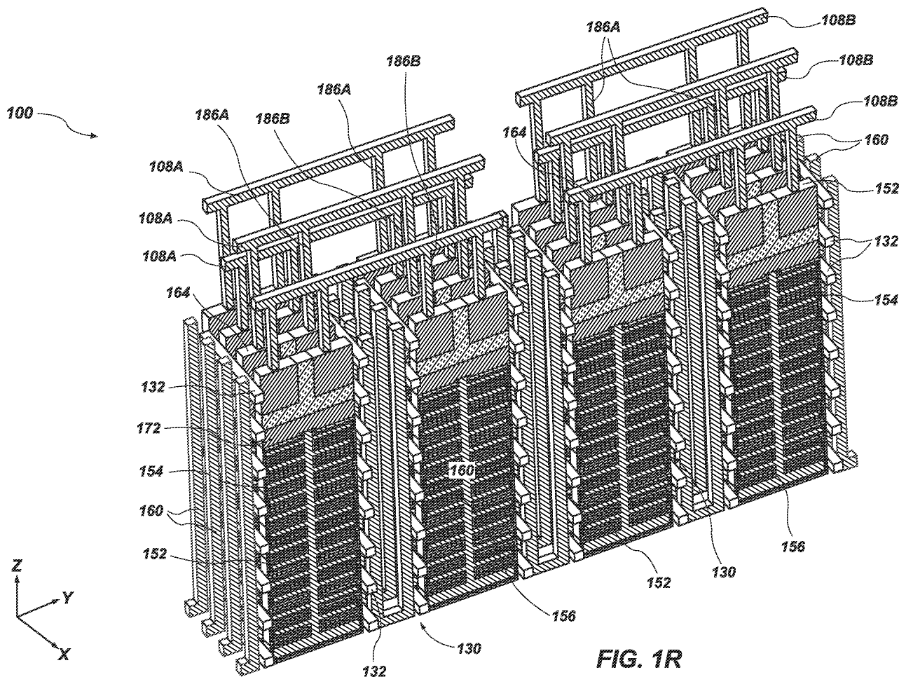

FIG. 1A through FIG. 1R are simplified partial top-down views (FIG. 1A and FIG. 1Q), simplified partial cross-sectional views (FIG. 1B through FIG. 1D and FIG. 1F through FIG. 1P), and simplified partial perspective views (FIG. 1E and FIG. 1R) illustrating a method of forming a first microelectronic device structure 100 (e.g., a memory device, such as a 3D DRAM memory device), in accordance with embodiments of the disclosure. With the description provided below, it will be readily apparent to one of ordinary skill in the art that the methods and structures described herein with reference to FIG. 1A through FIG. 1R may be used in various devices and electronic systems. The first microelectronic device structure 100 may also be referred to herein as a first die or a first wafer.

FIG. 1A is a simplified partial top-down view of the first microelectronic device structure 100; FIG. 1B is a simplified partial cross-sectional view of the first microelectronic device structure 100 taken through section line B-B of FIG. 1A; FIG. 1C is a simplified partial cross-sectional view of the first microelectronic device structure 100 taken through section line C-C of FIG. 1A; FIG. 1D is a simplified partial cross-sectional view of the first microelectronic device structure 100 taken through section line D-D of FIG. 1A; and FIG. 1E is simplified partial perspective view of a portion of the first microelectronic device structure 100.

Referring to FIG. 1A, the first microelectronic device structure 100 includes an array region 101 (also referred to herein as a “memory array region”) and one or more peripheral regions 103 located external to the array region 101. In some embodiments, the peripheral regions 103 horizontally (e.g., in at least X-direction) surround the array region 101. In some embodiments, the peripheral regions 103 substantially surround all horizontal sides of the array region 101 in a first horizontal direction (e.g., the X-direction). In other embodiments, the peripheral regions 103 substantially surround all horizontal boundaries (e.g., an entire horizontal area) of the array region 101.

The peripheral regions 103 may include first conductive contact exit regions 102 horizontally neighboring (e.g., in the X-direction) the array region 101. In some embodiments, the first conductive contact exit regions 102 horizontally extend (e.g., in the Y-direction) substantially an entire length (e.g., in the Y-direction) of the first microelectronic device structure 100. In other embodiments, portions of the peripheral regions 103 horizontally between (e.g., in the Y-direction) horizontally neighboring (e.g., in the Y-direction) first conductive contact exit regions 102 may comprise so-called “socket regions” including conductive contact structures for electrically connecting the first microelectronic device structure 100 to an additional microelectronic device structure, a power source, or both.

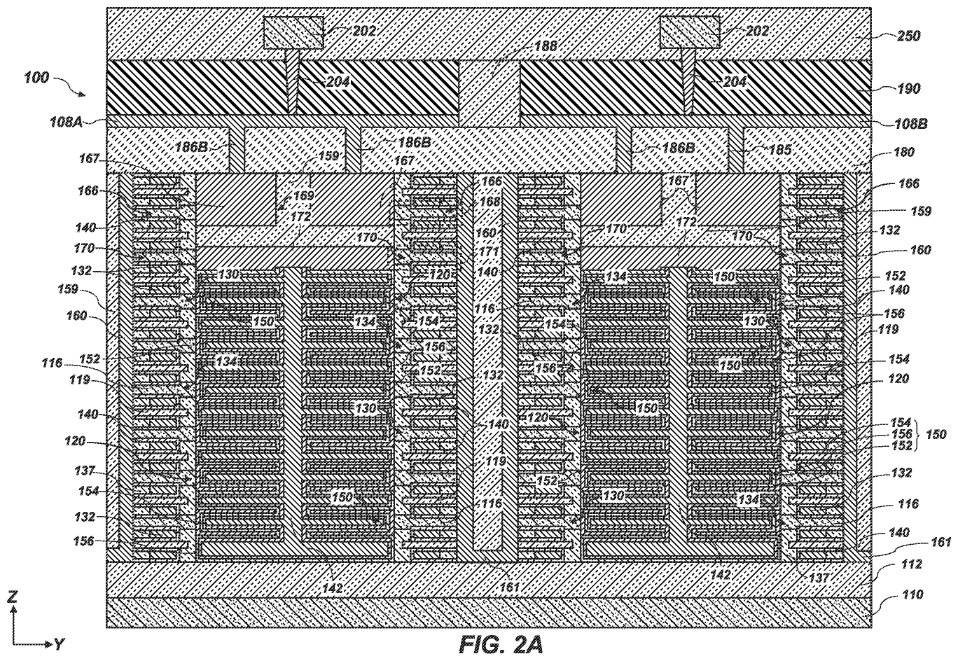

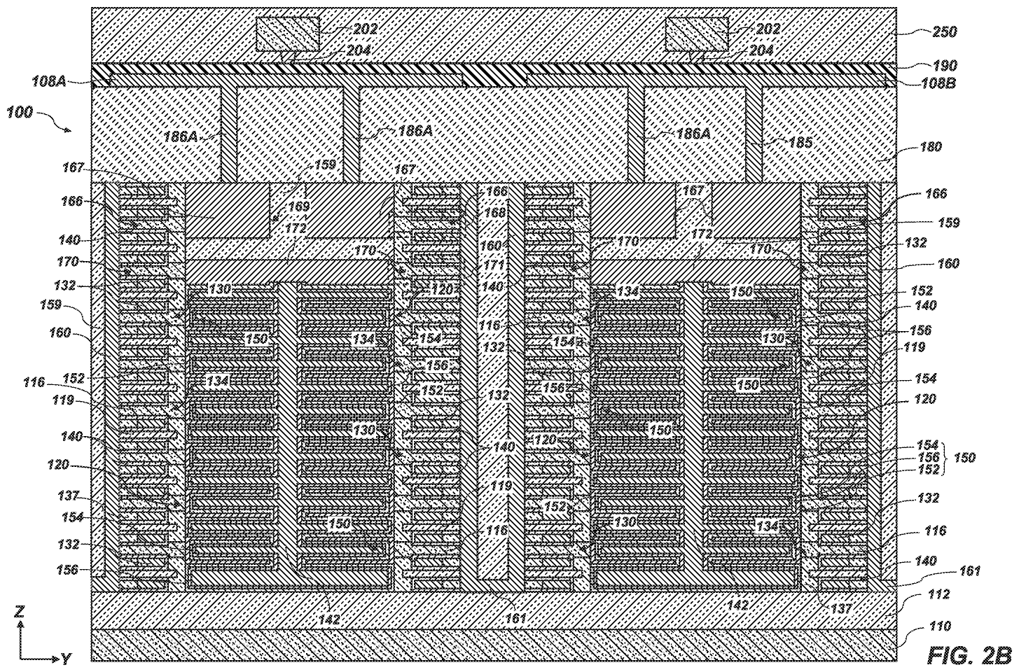

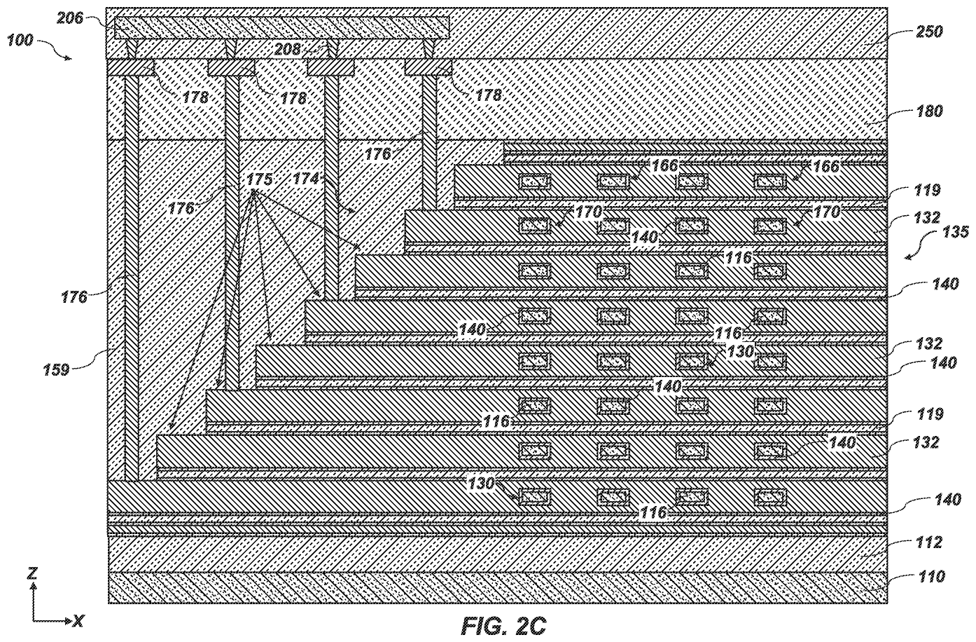

The first conductive contact exit regions 102 may be formed to include first conductive contact structures 176 for electrically connecting one or more components of the first microelectronic device structure 100 to circuitry of a second microelectronic device structure (e.g., second microelectronic device structure 250 (FIG. 2A through FIG. 2C)).

In some embodiments, each of the first conductive contact exit regions 102 exhibits about a same size (e.g., horizontal area in the XY plane) as each of the other of the first conductive contact exit regions 102. In other embodiments, at least some of the first conductive contact exit region 102 have a different size than other of the first conductive contact exit regions 102. In some embodiments, first conductive contact exit regions 102 at horizontal ends (e.g., in the Y-direction) of the first microelectronic device structure 100 have a smaller horizontal area (e.g., in the XY plane) than first conductive contact exit region 102 between horizontal ends (e.g., in the Y-direction) of the first microelectronic device structure 100.

Second conductive contact exit regions 106 may horizontally neighbor (e.g., in the X-direction) the first conductive contact exit regions 102 of the peripheral regions 103. In some embodiments, the second conductive contact exit regions 106 are located at horizontal ends (e.g., in the Y-direction) of the array region 101. The second conductive contact exit regions 106 may be formed to include second conductive contact for electrically connecting one or more components of the first microelectronic device structure 100 (e.g., global digit lines 108 (FIG. 1N through FIG. 1O)) to circuitry of a second microelectronic device structure (e.g., the second microelectronic device structure 250 (FIG. 2A through FIG. 2C)) at a processing stage subsequent to that illustrated in FIG. 1A.

Each of the second conductive contact exit regions 106 may exhibit about a same size (e.g., horizontal area in the XY plane) as the other of the second conductive contact exit regions 106. In some embodiments, one or more (e.g., each) of the second conductive contact exit regions 106 exhibits a different size than one or more of (e.g., each of) the first conductive contact exit regions 102.

With reference to FIG. 1A and FIG. 1B, within the array region 101, the first microelectronic device structure 100 includes vertical (e.g., in the Z-direction) stacks of memory cells 120 over a first base structure 110. Each vertical stack of memory cells 120 comprises a vertical stack of access devices 130 and a vertical stack of storage devices 150, the storage devices 150 of the vertical stack of storage devices 150 coupled to the access devices 130 of the vertical stack of access devices 130. The vertical stack of access devices 130 may horizontally neighbor (e.g., in the X-direction) the vertical stack of storage devices 150. The vertical stacks of memory cells 120 may individually include vertically spaced (e.g., in the Z-direction) levels of memory cells 120, each memory cell 120 individually comprising a storage device 150 horizontally neighboring an access device 130.

The vertical stacks of memory cells 120 may individually include vertically spaced (e.g., in the Z-direction) levels of memory cells 120, each memory cell 120 individually comprising a storage device 150 horizontally neighboring an access device 130. Although FIG. 1A illustrates sixty-four (64) vertical stacks of memory cells 120 (e.g., eight (8) rows and eight (8) columns of the vertical stacks of memory cells 120), the disclosure is not so limited, and the first array region 101 may include greater than sixty-four vertical stacks of memory cells 120.

The first base structure 110 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the first base structure 110 comprises a silicon wafer.

In some embodiments, the first base structure 110 includes different layers, structures, devices, and/or regions formed therein and/or thereon. In some embodiments, the first base structure 110 includes complementary metal-oxide-semiconductor (CMOS) circuitry and devices configured for effectuating operation of the vertical stacks of memory cells 120 of the first microelectronic device structure 100.

With reference to FIG. 1B, the first base structure 110 may be electrically isolated from the vertical stacks of memory cells 120 by a first insulative material 112 vertically intervening (e.g., in the Z-direction) between the first base structure 110 and the vertical stacks of memory cells 120. The first insulative material 112 may be formed of and include insulative material such as, for example, one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 112 comprises silicon dioxide.

Each access device 130 of the vertical stack of access devices 130 individually includes a channel region 134 comprising a channel material 116 in electrical communication with at least a portion of the horizontally neighboring (e.g., in the Y-direction) the storage device 150 (e.g., a first electrode 152 of the horizontally neighboring storage device 150).

The channel material 116 may be formed of and include, for example, a semiconductive material (e.g., silicon). In some embodiments, the channel material 116 comprises silicon, such as epitaxially grown silicon. In some embodiments, the channel material 116 comprises a semiconductive material (e.g., polysilicon) doped with at least one N-type dopant or at least one P-type dopant. In some embodiments, at least some portions of the channel material 116 are doped with one of at least one N-type dopant (e.g., at least one of arsenic ions, phosphorous ions, and antimony ions) and at least one P-type dopant (e.g., boron ions) and at least other portions of the channel material 116 are doped with the other of the at least one N-type dopant and the at least one P-type dopant to form the channel region 134.

Each of the access devices 130 may individually be operably coupled to one or more conductive structures 132 (FIG. 1A through FIG. 1C) (also referred to herein as “first conductive lines,” “access lines,” or “word lines”). With reference to FIG. 1C, the conductive structures 132 vertically overlying (e.g., in the Z-direction) and within horizontal boundaries (e.g., in the X-direction, in the Y-direction) of one another may form a vertical stack structure 135 of conductive structures 132. The vertical stack structure 135 comprises levels of the conductive structures 132 vertically (e.g., in the Z-direction) spaced from one another.

The conductive structures 132 may extend horizontally (e.g., in the X-direction; FIG. 1A) through first microelectronic device structure 100 (e.g., through the vertical stacks of memory cells 120) as lines (e.g., word lines) and may each be configured to be operably coupled to a vertically neighboring (e.g., in the Z-direction) access device 130 (e.g., the channel region 134 of a neighboring access device 130). In other words, a conductive structure 132 may be configured to be operably coupled to a vertically neighboring access device 130. With reference to FIG. 1C, the access devices 130 may individually be located vertically between (e.g., in the Z-direction) portions of a conductive structure 132. In some embodiments, the access devices 130 are individually located vertically within (e.g., in the Z-direction) vertical boundaries of a conductive structure 132.

The conductive structures 132 may individually be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the conductive structures 132 individually comprise tungsten. In other embodiments, the conductive structures individually comprise copper.

The conductive structures 132 may individually be configured to provide sufficient voltage to the channel region 134 directly vertically neighboring (e.g., in the Z-direction) the respective access device 130 to electrically couple a storage device 150 horizontally neighboring (e.g., in the Y-direction) and associated with the access device 130 to, for example, a conductive pillar structure (e.g., conductive pillar structure 160, also referred to as a “local digit line”) vertically extending (e.g., in the Z-direction) through or proximate the vertical stack of access devices 130 of the vertical stack of memory cells 120. Stated another way, each conductive structure 132 may individually comprise a gate structure configured to provide a sufficient voltage to the channel region 134 vertically neighboring (e.g., in the Z-direction) the conductive structure 132 to electrically couple the access device 130 including the channel region 134 to the horizontally neighboring (e.g., in the Y-direction) storage device 150.

The vertical stack structure 135 of the conductive structures 132 including the vertically spaced conductive structures 132 may intersect the vertical stacks of memory cells 120, such as the vertical stacks of the access devices 130 of the vertical stacks of memory cells 120, each of the conductive structures 132 of the vertical stack structure 135 intersecting a level (e.g., a tier) of the memory cells 120 of the vertical stack of memory cells 120. Each conductive structure 132 may intersect and comprise a portion of a plurality of vertical stacks of access devices 130 (e.g., a gate of the access devices 130).

With reference to FIG. 1A, each vertical stack structure 135 individually extends through and intersects several vertical stacks of access devices 130 of the vertical stack of memory cells 120. In some embodiments, each vertical stack structure 135 extends through horizontally neighboring (e.g., in the X-direction) vertical stacks of memory cells 120. In some embodiments, the vertical stack structures 135 extending in a first horizontal direction (e.g., in the X-direction) are spaced from each other in a second horizontal direction (e.g., in the Y-direction).

Although FIG. 1A and FIG. 1B illustrate that the conductive structures 132 of the vertical stack structure 135 individually intersect and form portions of eight (8) of the vertical stacks of memory cells 120, the disclosure is not so limited. In other embodiments, conductive structures 132 of the vertical stack structure 135 individually intersect and form portions of fewer than eight (8) of the vertical stacks of memory cells 120, such as four (4) of the vertical stacks of the memory cells 120, five (5) of the vertical stacks of the memory cells 120, or six (6) of the vertical stacks of memory cells 120. In other embodiments, conductive structures 132 of the vertical stack structure 135 individually intersect and form portions of more than eight (8) of the vertical stacks of memory cells 120, more than ten (10) of the vertical stacks of the memory cells 120, more than twelve (12) of the vertical stacks of the memory cells 120, more than sixteen (16) of the vertical stacks of the memory cells 120, or more than twenty (20) of the vertical stacks of the memory cells 120.

In some embodiments, vertically neighboring (e.g., in the Z-direction) conductive structures 132 between vertically neighboring (e.g., in the Z-direction) access devices 130 are spaced from each other by a second insulative material 119.

The second insulative material 119 may be formed of and include an insulative material that is different than, and that has an etch selectivity with respect to, the channel material 116. In some embodiments, the second insulative material 119 is formed of and includes one or more of the materials described above with reference to the first insulative material 112. In some embodiments, the second insulative material 119 is formed of and include an oxide material (e.g., silicon dioxide).

With combined reference to FIG. 1B and FIG. 1C, each of the access devices 130 is surrounded by the dielectric material 140, which may also be referred to herein as a “gate dielectric material.” The channel region 134 is separated from the conductive structures 132 by the dielectric material 140. In other words, the conductive structures 132 are separated from the access devices 130 by the dielectric material 140. In some embodiments, the portion of the conductive structure 132 directly vertically neighboring (e.g., in the Z-direction) and located within horizontal boundaries (e.g., in the X-direction, in the Y-direction) of the dielectric material 140 may be referred to as a “gate electrode.”

In some embodiments, and as illustrated in FIG. 1C, each of the access devices 130 is substantially surrounded by the dielectric material 140 that is, in turn, substantially surrounded by the conductive structure 132. In some such embodiments, the access devices 130 may individually comprise so-called “gate all around” access devices (e.g., gate all around transistors) since each of the access devices 130 is individually substantially surrounded by one of the conductive structures 132.

The dielectric material 140 may be formed of and include insulative material. By way of non-limiting example, the dielectric material 140 may comprise one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride, another gate dielectric material, a dielectric carbon nitride material (e.g., silicon carbon nitride (SiCN)), or a dielectric carboxynitride material (e.g., silicon carboxynitride (SiOCN)).

With continued reference to FIG. 1C, in some embodiments, the dielectric material 140 is also be located on surfaces of the conductive structures 132 and between the conductive structures 132 and the second insulative material 119. Portions of the dielectric material 140 on surfaces of the second insulative material 119 may not be referred to as a “gate dielectric” material.

With reference back to FIG. 1B, vertically neighboring (e.g., in the Z-direction) access devices 130 are spaced from one another by a fourth insulative material 137. In some embodiments, the fourth insulative material 137 surrounds at least a portion of the dielectric material 140. The fourth insulative material 137 may be formed of and include insulative material. In some embodiments, the fourth insulative material 137 comprises silicon nitride.

With reference to FIG. 1B, in some embodiments, the storage devices 150 are in electrical communication with a conductive plate structure 142 (not illustrated in FIG. 1A for clarity and ease of understanding the description). The conductive plate structure 142 may be formed of and include conductive material, such as one or more of the materials of an electrode (e.g., a second electrode 154) of the storage devices 150. In some embodiments, the conductive plate structure 142 comprises substantially the same material composition as an electrode of the storage devices 150. In other embodiments, the conductive plate structure 142 comprises a different material composition than the electrodes of the storage devices 150. The conductive plate structures 142 may be referred to herein as “conductive plates” or “ground structures.” The conductive plate structures 142 horizontally extend (e.g., in the X-direction) as conductive plates. In some embodiments, and with reference to FIG. 1A, the conductive plate structures 142 horizontally extend in substantially the same direction and are substantially parallel to the conductive structures 132. The conductive plate structures 142 may be horizontally between (e.g., in the Y-direction) vertical stacks of memory cells 120, such as between vertical stacks of storage devices 150.

The vertical stacks of storage devices 150 vertically overlie (e.g., in the Z-direction) the first base structure 110. Each of the storage devices 150 individually comprises a first electrode 152 (also referred to herein as an “outer electrode,” “a first electrode plate,” or a “first node structure”), a second electrode 154 (also referred to herein as an “inner electrode,” “a second electrode plate,” or a “second node structure”), and a dielectric material 156 between the first electrode 152 and the second electrode 154. In some such embodiments, the storage devices 150 individually comprise capacitors. However, the disclosure is not so limited and in other embodiments, the storage devices 150 may each individually comprise other structures, such as, for example, phase change memory (PCM), resistance random-access memory (RRAM), conductive-bridging random-access memory (conductive bridging RAM), or another structure for storing a logic state.

At least a portion of each storage device 150 is in electrical communication with a horizontally neighboring (e.g., in the X-direction) access device 130. In some embodiments, the first electrode 152 of each storage device 150 is in electrical communication with (and directly contacts) a horizontally neighboring access device 130.

The first electrode 152 may be formed of and include conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium), polysilicon, and other materials exhibiting electrical conductivity. In some embodiments, the first electrode 152 comprises titanium nitride.

The second electrode 154 may be formed of and include conductive material. In some embodiments, the second electrode 154 comprises one or more of the materials described above with reference to the first electrode 152. In some embodiments, the second electrode 154 comprises substantially the same material composition as the first electrode 152.

The dielectric material 156 may be formed of and include one or more of silicon dioxide (SiO₂), silicon nitride (Si₃N₄), polyimide, titanium dioxide (TiO₂), tantalum oxide (Ta₂O₅), aluminum oxide (Al₂O₃), an oxide-nitride-oxide material (e.g., silicon dioxide-silicon nitride-silicon dioxide), strontium titanate (SrTiO₃) (STO), barium titanate (BaTiO₃), hafnium oxide (HfO₂), zirconium oxide (ZrO₂), a ferroelectric material (e.g., ferroelectric hafnium oxide, ferroelectric zirconium oxide, lead zirconate titanate (PZT)), and a high-k dielectric material.

The second electrode 154 may be in electrical communication with one of the conductive plate structures 142 of a vertical stack of memory cells 120. In some embodiments, the second electrodes 154 are substantially integral with the conductive plate structures 142. With reference to FIG. 1B, in some embodiments, the second electrodes 154 (FIG. 1B) of horizontally neighboring (e.g., in the X-direction) vertical stacks of storage devices 150 are in electrical communication with the same conductive plate structure 142. In some embodiments, the conductive plate structures 142 are individually formed of conductive material, such as one or more of the materials of the second electrode 154. In some embodiments, the conductive plate structures 142 comprise substantially the same material composition as the second electrode 154. In other embodiments, the conductive plate structures 142 comprise a different material composition than the second electrode 154.

With reference to FIG. 1A, FIG. 1B, and FIG. 1E, the first microelectronic device structure 100 may include conductive pillar structures 160 vertically (e.g., in the Z-direction) extending through the first microelectronic device structure 100. The conductive pillar structures 160 may also be referred to herein as “digit lines,” “second conductive lines,” “digit line pillar structures,” “local digit lines,” or “vertical digit lines.” The conductive pillar structures 160 may be electrically coupled to the access devices 130 to facilitate operation of the memory cells 120 of a vertical stack of memory cells 120. Stated another way, each conductive pillar structure 160 vertically extends directly horizontally neighboring (e.g., in the Y-direction) and in contact with access devices 130 of a vertical stack of memory cells 120. In some embodiments, each vertical stack of memory cells 120 includes one of the conductive pillar structures vertically extending (e.g., in the Z-direction) and horizontally neighboring (e.g., in the Y-direction) the vertical stack of memory cells 120 (e.g., proximate the vertical stack of access devices 130 of the memory cells 120). As described above, application of a voltage to a conductive structure 132 vertically neighboring (e.g., in the Z-direction) the channel material 116 of the channel region 134 of a vertically neighboring access device 130 may induce a current through the channel region 134 to electrically connect the conductive pillar structure 160 to the storage device 150 horizontally neighboring (e.g., in the Y-direction) the access device 130.

In some embodiments, the conductive pillar structures 160 in horizontally neighboring (e.g., in the Y-direction) vertical stack structures 135 are horizontally aligned (e.g., in the X-direction) with each other. In other embodiments, conductive pillar structures 160 in horizontally neighboring (e.g., in the Y-direction) vertical stack structures 135 are horizontally aligned (e.g., in the X-direction) with each other.

In some embodiments, the conductive pillar structures 160 of horizontally neighboring (e.g., in the Y-direction) vertical stacks of memory cells 120 are in electrical communication with one another through a conductive portion 161 located at a vertically lower (e.g., in the Z-direction) portion of the first microelectronic device structure 100 (e.g., directly above the first insulative material 112). In other embodiments, the conductive pillar structures 160 in electrical communication with horizontally neighboring (e.g., in the Y-direction) vertical stacks of memory cells 120 are electrically isolated from one another (e.g., do not include the conductive portion 161 horizontally extending (e.g., in the Y-direction) between horizontally neighboring conductive pillar structures 160.

The conductive pillar structures 160 may individually be formed of and include conductive material, such as one or more of a metal (e.g., one or more of tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the conductive pillar structures 160 comprise tungsten.

With continued reference to FIG. 1B, in some embodiments, vertically uppermost (e.g., in the Z-direction) access devices 130 form a multiplexer 166, one of which is illustrated in box 168 in FIG. 1B. In some embodiments, and as described in further detail herein, global digit lines (e.g., first global digit lines 108A (FIG. 1N, FIG. 1P through FIG. 1R), second global digit lines 108B (FIG. 1N, FIG. 1O, FIG. 1Q, FIG. 1R)) are individually in electrical communication with a multiplexer 166 to selectively couple the global digit line to one of the conductive pillar structures 160 through the multiplexer 166. In some embodiments, the multiplexers 166 are individually in electrical communication with a conductive structure 169 horizontally neighboring (e.g., in the Y-direction) the multiplexer 166. The conductive structure 169 may include, for example, a conductive material 167. The conductive material 167 may be formed of and include conductive material, such as one or more of the materials described above with reference to the first electrode 152. In other embodiments, the conductive structure 169 comprises the first electrode 152 and the second electrode 154, and the conductive material 167 between the first electrode 152 and the second electrode 154. In some such embodiments, the conductive structures 169 are formed by selectively removing the dielectric material 156 from between the first electrode 152 and the second electrode 154 of the vertically uppermost (e.g., in the Z-direction) levels of the vertical stack of memory cells 120 and forming the conductive material 167 at locations corresponding to the dielectric material 156.

Horizontally neighboring (e.g., in the Y-direction) multiplexers 166 may be electrically isolated from one another by a third insulative material 159. In some embodiments, the third insulative material 159 electrically isolates horizontally neighboring (e.g., in the Y-direction) conductive structures 169 from one another.

The third insulative material 159 may be formed of and include insulative material, such as one or more of the materials described above with reference to the first insulative material 112. In some embodiments, the third insulative material 159 comprises silicon dioxide.

With continued reference to FIG. 1B, in some embodiments, access devices 130 vertically (e.g., in the Z-direction) neighboring (e.g., vertically below) the multiplexers 166 may individually comprise a transistor 170, one of which is illustrated in box 171, configured to electrically couple a horizontally neighboring (e.g., in the X-direction) conductive pillar structure 160 to the conductive plate structure 142 through conductive structures 172. The transistor 170 may comprise a so-called “bleeder” transistor or a “leaker” transistor configured to provide a bias voltage to the conductive pillar structures 160 to which it is coupled (e.g., the horizontally neighboring (e.g., in the X-direction) conductive pillar structures 160). In some embodiments, the conductive structure 132 coupled to the transistors 170 may be in electrical communication with a voltage, such as a drain voltage V_{dd} or a voltage source supply Vₛₛ. In use and operation, the transistors 170 are configured to provide a negative voltage to the conductive pillar structures 160 of unselected (e.g., inactive) vertical stacks of memory cells 120. In other words, the transistors 170 are configured to electrically connect unselected conductive pillar structures 160 with their respective conductive plate structures 142 (e.g., ground structures, cell plates), which may be coupled to a negative voltage. In some embodiments, each vertical stack of memory cells 120 includes at least one (e.g., one) of the multiplexers 166 and at least one (e.g., one) of the transistors 170.

In some embodiments, the transistors 170 of horizontally neighboring (e.g., in the Y-direction) vertical stacks of memory cells 120 are in electrical communication with each other via the conductive structures 172. In some embodiments, for every conductive structure 172 in electrical communication with two horizontally neighboring transistors 170, the first microelectronic device structure 100 includes two conductive structures 169 each individually in electrical communication with a separate one of the multiplexers 166. Stated another way, in some embodiments, the multiplexers of horizontally neighboring (e.g., in the Y-direction) vertical stacks of access devices 130 are electrically isolated from one another and the transistors 170 are in electrical communication with one another by means of the conductive structure 172.

In some embodiments, the transistors 170 are electrically isolated from the multiplexers 166 by the third insulative material 159. In some such embodiments, the third insulative material 159 electrically isolates, for example, the conductive structures 172 in electrical communication with the transistors 170 from the conductive structures 169 in electrical communication with the multiplexers 166.

In some embodiments, the conductive structure 172 extend substantially an entire length (e.g., in the Y-direction) between horizontally neighboring (e.g., in the Y-direction) transistors 170.

The conductive structures 172 may be formed of and include conductive material, such as one or more of the materials described above with reference to the conductive pillar structures 160. In some embodiments, the conductive structures 172 comprise titanium nitride. In other embodiments, the conductive structures 172 comprise copper. In yet other embodiments, the conductive structures 172 comprise tungsten.

With collective reference to FIG. 1A and FIG. 1C, the conductive structures 132 of the vertical stack structure 135 may horizontally (e.g., in the X-direction) terminate at staircase structures 174 located at horizontally (e.g., in the X-direction) terminal portions of the vertical stack structure 135. While the staircase structures 174 are illustrated in FIG. 1A, it will be understood that the staircase structures 174 are located beneath a vertically upper (e.g., in the Z-direction) surface of the first microelectronic device structure 100. With reference to FIG. 1C, vertically higher (e.g., in the Z-direction) conductive structures 132 may have a smaller horizontal dimension (e.g., in the X-direction) than vertically lower conductive structures 132, such that horizontal edges of the conductive structures 132 at least partially define steps 175 of the staircase structures 174. In some embodiments, the memory cells 120 of the vertical stack of memory cells 120 that are vertically higher (e.g., in the Z-direction) than other memory cells 120 comprise are intersected by conductive structures 132 having a smaller horizontal dimension (e.g., in the X-direction) than conductive structures 132 of vertically lower memory cells 120 of the vertical stacks of memory cells 120. In some embodiments, a horizontal dimension (e.g., in the X-direction) of the conductive structures 132 of the multiplexers 166 may be less than a horizontal dimension (e.g., in the X-direction) of the conductive structures 132 of the transistors 170, which may be less than a horizontal dimension (e.g., in the X-direction) of the conductive structures 132 intersecting the memory cells 120.

With reference to FIG. 1A, in some embodiments, the staircase structures 174 of each of the vertical stack structure 135 are horizontally aligned in a first direction (e.g., in the X-direction) and horizontally offset in a second direction (e.g., the Y-direction). In some such embodiments, each vertical stack structure 135 individually includes a staircase structure 174 at a first horizontal end (e.g., in the X-direction) of the vertical stack structure 135 and an additional staircase structure 174 at a second, opposite horizontal end (e.g., in the X-direction) of the vertical stack structure 135.

In other embodiments, the staircase structures 174 of horizontally neighboring (e.g., in the Y-direction) vertical stack structures 135 may be located at opposing horizontal ends (e.g., in the X-direction) of the first microelectronic device structure 100. In some such embodiments, every vertical stack structure 135 of conductive structures 132 (e.g., in the Y-direction) includes a staircase structure 174 at a first horizontal end (e.g., in the X-direction) of the first microelectronic device structure 100 while the other vertical stack structures 135 of conductive structures 132 individually includes a staircase structure 174 at a second horizontal end (e.g., in the X-direction) of the first microelectronic device structure 100 opposite the first horizontal end. Stated another way, the staircase structures 174 of horizontally neighboring (e.g., in the Y-direction) conductive structures 132 may alternate between a first horizontal end (e.g., in the X-direction) of the first microelectronic device structure 100 and a second horizontal end (e.g., in the X-direction) of the first microelectronic device structure 100, the second horizontal end opposing the first horizontal end. Accordingly, although FIG. 1A illustrates two staircase structures 174 for every vertical stack structure 135 (e.g., a staircase structure 174 at each horizontal end (e.g., in the X-direction) of each vertical stack structure 135), the disclosure is not so limited. In other embodiments, the vertical stack structures 135 may include one staircase structure 174 at only one horizontal end (e.g., in the X-direction) of the vertical stack structure 135.

The staircase structures 174 may be located within the first conductive contact exit regions 102 (FIG. 1A) of the peripheral regions 103 (FIG. 1A). With reference to FIG. 1A, in some embodiments, the staircase structures 174 of each of the vertical stack structures 135 are horizontally aligned in a first direction (e.g., in the X-direction) and horizontally offset in a second direction (e.g., the Y-direction). In some such embodiments, the staircase structure 174 of each vertical stack structure 135 may be located at a first horizontal end (e.g., in the X-direction) of the first microelectronic device structure 100.

The quantity of the steps 175 may correspond to the quantity of the levels of memory cells 120 of the vertical stack (plus one level for the multiplexers 166 and one level for the transistors 170). In some embodiments, a quantify of the steps 175 of the vertical stack structure 135 equals the number of levels of memory cells 120 of the vertical stack of memory cells 120 plus two (e.g., one for the level of the multiplexers 166 and one for the level of the transistors 170). Although FIG. 1A and FIG. 1C illustrate that the staircase structures 174 individually comprise a particular number (e.g., eight (8)) steps 175, the disclosure is not so limited. In other embodiments, the staircase structures 174 each individually include a desired quantity of the steps 175, such as within a range from thirty-two (32) of the steps 175 to two hundred fifty-six (256) of the steps 175. In some embodiments, the staircase structures 174 each individually include sixty-four (64) of the steps 175. In other embodiments, the staircase structures 174 each individually include ninety-six (96) or more of the steps 175. In some such embodiments, each vertical stack of memory cells 120 of the first microelectronic device structure 100 individually includes a corresponding quantity memory cells 120 (e.g., minus one memory cell 120 for the multiplexer 166 and one memory cell 120 for the transistor 170). In other embodiments, the staircase structures 174 each individually include a different number of the steps 175, such as less than sixty-four (64) of the steps 175 (e.g., less than or equal to sixty (60) of the steps 175, less than or equal to fifty (50) of the steps 175, less than about forty (40) of the steps 175, less than or equal to thirty (30) of the steps 175, less than or equal to twenty (20) of the steps 175, less than or equal to ten (10) of the steps 175); or greater than sixty-four (64) of the steps 175 (e.g., greater than or equal to seventy (70) of the steps 175, greater than or equal to one hundred (100) of the steps 175, greater than or equal to about one hundred twenty-eight (128) of the steps 175, greater than two hundred fifty-six (256) of the steps 175).

In some embodiments, the staircase structures 174 each individually include the same quantity of the steps 175. In some such embodiments, staircase structures 174 of the same vertical stack structure 135 include the same quantity of the steps 175. In some embodiments, each step 175 of each staircase structure 174 may be vertically offset (e.g., in the Z-direction) from a vertically neighboring step 175) of the staircase structure 174 by one level (e.g., one tier) of the vertically alternating conductive structures 132 and the vertically intervening (e.g., in the Z-direction) dielectric material 140 and second insulative material 119. In some such embodiments, every conductive structure 132 of the vertical stack structure 135 may comprise a step 175 at each horizontal end (e.g., in the X-direction) of the staircase structures 174 of the vertical stack structure 135. In other embodiments, vertically neighboring (e.g., in the Z-direction) steps 175 of a staircase structure 174 on a first horizontal size (e.g., in the X-direction) of a vertical stack structure 135 may be vertically offset (e.g., in the Z-direction) by two levels (e.g., two tiers) of the vertically alternating conductive structures 132 and the vertically intervening dielectric material 140 and second insulative material 119. In some such embodiments, the steps 175 of each staircase structure 174 are formed of every other conductive structure 132 of the vertical stack structure 135 and the steps 175 of staircase structures 174 at horizontally opposing ends (e.g., in the X-direction) of the same vertical stack structure 135 may be defined by conductive structures 132 that are vertically spaced (e.g., in the Z-direction) from one another by one level of a conductive structure 132 and the vertically intervening dielectric material 140 and second insulative material 119.

With continued reference to FIG. 1A and FIG. 1C, first conductive contact structures 176 may be in electrical communication with individual conductive structures 132 at the steps 175. For example, the first conductive contact structures 176 may individually physically contact (e.g., land on) portions of upper surfaces of the conductive structures 132 at least partially defining treads of the steps 175. In some embodiments, each step 175 may be in electrical communication with a first conductive contact structure 176 at the horizontal (e.g., in the X-direction) end of the staircase structure 174. In other embodiments, every other step 175 of the staircase structures 174 may include a first conductive contact structure 176 in contact therewith. In other words, every other step 175 of the staircase structures 174 may individually be in contact with a first conductive contact structure 176. In some such embodiments, each vertical stack structure 135 may include one staircase structure 174 at each horizontal (e.g., in the X-direction) end thereof and each step 175 of a first staircase structure 174 at a first horizontal end of the vertical stack structures 135 not in electrical communication with a first conductive contact structure 176 may individually be in electrical communication with a first conductive contact structure 176 at a second staircase structure 174 at a second, opposite horizontal end of the vertical stack structure 135.

The first conductive contact structures 176 may individually be formed of and include conductive material, such as one or more of the materials described above with reference to the conductive pillar structures 160. In some embodiments, the first conductive contact structures 176 comprise substantially the same material composition as the conductive pillar structures 160. In other embodiments, the first conductive contact structures 176 comprise a different material composition than the conductive pillar structures 160. In some embodiments, the first conductive contact structures 176 comprise tungsten.

First pad structures 178 may vertically overlie and individually be in electrical communication with of the first conductive contact structures 176. Each of the first conductive contact structures 176 is individually in electrical communication with one of the first pad structures 178. The first pad structure 178 may be formed within a fifth insulative material 180.

The first pad structures 178 are individually formed of and include conductive material, such as one or more of the materials described above with reference to the global digit lines 108. In some embodiments, the first pad structures 178 are formed of and include tungsten. In other embodiments, the first pad structures 178 are formed of and include copper.

The fifth insulative material 180 may be formed of and include one or more of the materials described above with reference to the first insulative material 112. In some embodiments, the fifth insulative material 180 comprises substantially the same material composition as the first insulative material 112. In some embodiments, the fifth insulative material 180 comprises silicon dioxide.

FIG. 1D is a simplified, partial cross-sectional view of a portion of the array region 101 taken through section line D-D of FIG. 1A and illustrates a cross-section of the first microelectronic device structure 100 taken through horizontally neighboring (e.g., in the X-direction) vertical stacks of storage devices 150.

With reference to FIG. 1D, each of the storage devices 150 of the vertical stacks of memory cells 120 (and hence, each of the vertical stacks of memory cells 120) may be substantially evenly horizontally spaced (e.g., in the X-direction) from one another. In some embodiments, a pitch P₁ between horizontally neighboring (e.g., in the X-direction) vertical stacks of storage devices 150 (and the corresponding vertical stacks of memory cells 120) may be within a range of from about 80 nm to about 140 nm, such as from about 80 nm to about 100 nm, from about 100 nm to about 120 nm, or from about 120 nm to about 140 nm. In some embodiments, the pitch P₁ is from about 90 nm to about 120 nm. In some embodiments, the pitch P₁ corresponds to the horizontal pitch (e.g., in the X-direction) between horizontally neighboring (e.g., in the X-direction) of the conductive pillar structures 160 (and the pitch between horizontally neighboring columns of the vertical stacks of memory cells 120).

FIG. 1E is a simplified partial perspective view of the portion of the array region 101 of box E of the first microelectronic device structure 100 of FIG. 1A. In FIG. 1E, the first base structure 110, the first insulative material 112, the second insulative material 119, portions of the third insulative material 159, and the fifth insulative material 180 are not illustrated for clarity and ease of understanding the description. In addition, for clarity and ease of understanding the description, the channel material 116 of the access devices 130 is not illustrated in FIG. 1E, but it will be understood that the channel material 116 is located between and in electrical communication with the conductive pillar structures 160 and the storage devices 150, as described and illustrated with reference to FIG. 1B.

FIG. 1F and FIG. 1G are simplified partial cross-sectional views of the first microelectronic device structure 100 at a processing stage subsequent to the processing stage illustrated in FIG. 1A through FIG. 1E. FIG. 1F illustrates the same cross-section of the first microelectronic device structure 100 as that illustrated in FIG. 1D; and FIG. 1G illustrates the same cross-section of the first microelectronic device structure 100 as that illustrated in FIG. 1B.

With collective reference to FIG. 1F and FIG. 1G, trenches 181 may be formed within the fifth insulative material 180 and vertically overlying (e.g., in the Z-direction) every other one of the conductive pillar structures 160. In some embodiments, the horizontal boundaries (e.g., in the X-direction, in the Y-direction) of the conductive pillar structures 160 directly vertically underlying (e.g., in the Z-direction) are located within the horizontal boundaries (e.g., in the X-direction, in the Y-direction) of the trenches 181.

In some embodiments, a vertical depth D₁ of the trenches 181 is less than a vertical height H₁ between a vertically uppermost (e.g., in the Z-direction) surface of the fifth insulative material 180 and a vertically uppermost (e.g., in the Z-direction) of the conductive pillar structures 160. In some embodiments, the vertical depth D₁ of the trenches 181 is within a range of from about 30 percent to about 70 percent of the vertical height H₁, such as within a range of from about 30 percent to about 40 percent, from about 40 percent to about 50 percent, from about 50 percent to about 60 percent, or from about 60 percent to about 70 percent. In some embodiments, the vertical depth of the trenches 181 is about half of the vertical height H₁.

In some embodiments, the trenches 181 are formed by exposing the fifth insulative material 180 to an etching process (e.g., a dry etch, such as a reactive ion etch (RIE), a wet etch) for a sufficient duration to form the trenches 181 to the vertical depth D₁. In other words, the vertical depth D₁ to which the trenches 181 are formed may depend on the duration during which the fifth insulative material 180 is exposed to the etching conditions. By way of non-limiting example, the fifth insulative material 180 may be exposed to one or more of carbon tetrafluoride (CF₄), trifluromethane (CHF₃), hexafluoroethane (C₂F₆), octafluoropropane (C₃F₈), octafluorocyclobutane (C₅H₈), hydrogen (H₂), sulfur hexafluoride (SF₆), ammonia (NH₃), oxygen (O₂) for a sufficient duration to form the trenches 181 to the desired vertical depth D₁.

The vertical depth D₁ may be within a range of from about 110 nm to about 190 nm, such as from about 110 nm to about 130 nm, from about 130 nm to about 150 nm, from about 150 nm to about 170 nm, or from about 170 nm to about 190 nm. In some embodiments, the vertical depth D₁ is about 150 nm. However, the disclosure is not so limited and the vertical depth D₁ may be different than that described above.

With reference now FIG. 1H and FIG. 1I, after forming the trenches 181 (FIG. 1F, FIG. 1G), the trenches 181 are filled with a resist material 183. FIG. 1H is a simplified partial cross-sectional view of the first microelectronic device structure 100 illustrating the same cross-sectional view illustrated in FIG. 1F; and FIG. 1I is a simplified partial cross-sectional view of the first microelectronic device structure 100 illustrating the same cross-sectional view illustrated in FIG. 1G.

The resist material 183 may comprise, for example, a bottom antireflective coating (BARC) material. In some embodiments, the resist material 183 comprises an organic material, such as an organic polymer comprising carbon, oxygen, and nitrogen atoms.

FIG. 1J through FIG. 1L are simplified partial cross-sectional views of the first microelectronic device structure 100 at a processing stage subsequent to that illustrated in FIG. 1H and FIG. 1I. FIG. 1J is a simplified partial cross-sectional view of the first microelectronic device structure 100 illustrating the same cross-sectional view illustrated in FIG. 1H; FIG. 1K is a simplified partial cross-sectional view of the first microelectronic device structure 100 illustrating the same cross-sectional view illustrated in FIG. 1I; and FIG. 1L is a simplified partial cross-sectional view of the first microelectronic device structure 100 illustrating a different cross-section than that illustrated in FIG. 1K and parallel to the cross-sectional view of FIG. 1K. The cross-section of FIG. 1L illustrates a cross-sectional view of the first microelectronic device structure 100 illustrating vertical stacks of memory cells 120 horizontally neighboring (e.g., in the X-direction) the vertical stacks of memory cells 120 illustrated in FIG. 1K (e.g., the cross-section of FIG. 1L illustrates a column of the vertical stacks of memory cells 120 horizontally neighboring (e.g., in the X-direction) the column of vertical stacks of memory cells 120 illustrated in FIG. 1K). The cross-section illustrated in FIG. 1K is taken through section line K-K of FIG. 1J; and the cross-section illustrated in FIG. 1L is taken through section line L-L of FIG. 1J.

With reference to FIG. 1J through FIG. 1L, contact openings 184 may be formed through the fifth insulative material 180 and the resist material 183 (FIG. 1H, FIG. 1I) to expose vertically upper surfaces (e.g., in the Z-direction) of the conductive pillar structures 160. In some embodiments, the fifth insulative material 180 vertically underlying (e.g., in the Z-direction) the resist material 183 is removed and the fifth insulative material 180 vertically overlying (e.g., in the Z-direction) the conductive pillar structures 160 horizontally between (e.g., in the X-direction) the resist material 183 is removed. In some embodiments, the contact openings 184 each individually expose substantially an entire vertically upper (e.g., in the Z-direction) surface of the conductive pillar structures 160.

With reference to FIG. 1J, after forming the contact openings 184 in the fifth insulative material 180 and the resist material 183 (FIG. 1H, FIG. 1I), the resist material 183 may be selectively removed (e.g., stripped) from the first microelectronic device structure 100. In some embodiments, removing the resist material 183 may horizontally extend (e.g., in the X-direction) a dimension D₂ of the trenches 181.

In some embodiments, the dimension D₂ (e.g., width) of the trenches 181 is within a range of from about 80 nm to about 120 nm, such as from about 80 nm to about 120 nm, such as from about 80 nm to about 100 nm, or from about 100 nm to about 120 nm. In some embodiments, the dimension D₂ is about 100 nm. However, the disclosure is not so limited and the dimension D₂ may be different than that described above. In some embodiments, the dimension D₂ is greater than the vertical depth D₁ of the trenches 181.

With continued reference to FIG. 1J, a dimension D₃ (e.g., a diameter) of the contact openings 184 may be within a range of from about 20 nm to about 60 nm, such as from about 20 nm to about 30 nm, from about 30 nm to about 40 nm, from about 40 nm to about 50 nm, or from about 50 nm to about 60 nm. In some embodiments, the dimension D₃ is about 35 nm.

With collective reference to FIG. 1J through FIG. 1L, in some embodiments, every other contact opening 184 vertically extends (e.g., in the Z-direction) through the fifth insulative material 180 and is located within the horizontal boundaries (e.g., in the X-direction, in the Y-direction) of the trenches 181 (FIG. 1J, FIG. 1K) and the other contact openings 184 are formed outside of the horizontal boundaries of the trenches 181 (e.g., horizontally between (e.g., in the X-direction) of the trenches 181).

FIG. 1M is a simplified partial cross-sectional view of the first microelectronic device structure 100 at a processing stage subsequent to that illustrated in FIG. 1J and FIG. 1L. FIG. 1M is a simplified partial cross-sectional view of the first microelectronic device structure 100 illustrating the same cross-sectional view illustrated in FIG. 1J.

With reference to FIG. 1M, conductive material 185 may be formed within the contact openings 184 (FIG. 1J through FIG. 1L) and the trenches 181 (FIG. 1J, FIG. 1K) and vertically over (e.g., in the Z-direction) surfaces of portions of the fifth insulative material 180 to form first global digit line contact structures 186A and second global digit line contact structures 186B within the contact openings 184 and preliminary global digit lines 187 in electrical communication with the global digit line contact structures 186. The first global digit line contact structures 186A and the second global digit line contact structures 186B are collectively referred to herein as “global digit line contact structures 186.” In some embodiments, in the cross-sectional illustrated in FIG. 1M, every other one of the global digit line contacts structures 186 (e.g., in the X-direction) is a first global digit line contact structure 186A and the other global digit line contact structures 186 is a second global digit line contact structure 186B.

The first global digit line contact structures 186A may have a vertical height H₂ larger than a vertical height H₃ of the second global digit line contact structures 186B. In some embodiments, the vertical height H₂ of the first global digit line contact structures 186A is about two times as large as the vertical height H₃ of the second global digit line contact structures 186B.

The global digit line contact structures 186 may individually be in electrical communication with the conductive structures 169 that are, in turn, in electrical communication with the multiplexers 166. By way of non-limiting example, the global digit line contact structures 186 are individually in electrical communication with conductive structures 169 by means of the conductive material 167, the first electrode 152, and the second electrode 154.

The conductive material 185 of the global digit line contact structures 186 and the preliminary global digit lines 187 may be formed of and include one or more of the materials described above with reference to the conductive pillar structures 160. In some embodiments, the conductive material 185 comprises titanium nitride. In other embodiments, the conductive material 185 comprises tungsten. In yet other embodiments, the conductive material 185 comprises copper.

In some embodiments, a pitch of the global digit line contact structures 186 in the horizontal direction (e.g., in the X-direction) is substantially the same as the pitch P₁ (FIG. 1D) of the vertical stacks of memory cells 120. In some embodiments, the pitch of the global digit line contact structures 186 (e.g., the pitch between a first global digit line contact structure 186A and a second global digit line contact structure 186B) is within a range of from about 80 nm to about 140 nm, such as from about 80 nm to about 100 nm, from about 100 nm to about 120 nm, or from about 120 nm to about 140 nm. In some embodiments, the pitch is from about 90 nm to about 120 nm.

After forming the global digit line contact structures 186 and the preliminary global digit lines 187, a sixth insulative material 188 may be formed vertically over (e.g., in the Z-direction) the global digit line contact structures 186 and the preliminary global digit lines 187. The sixth insulative material 188 may be formed of and include insulative material, such as one or more of the materials described above with reference to the first insulative material 112. In some embodiments, the sixth insulative material 188 comprises silicon dioxide.

FIG. 1N through FIG. 1R are simplified partial cross-sectional views of the first microelectronic device structure 100 at a processing stage subsequent to that illustrated in FIG. 1M. FIG. 1N is a simplified partial cross-sectional view of the first microelectronic device structure 100 illustrating the same cross-sectional view illustrated in FIG. 1M; FIG. 1O is a simplified partial cross-sectional view of the first microelectronic device structure 100 illustrating the same cross-sectional view illustrated in FIG. 1K and illustrates the cross-section of the first microelectronic device structure 100 taken through section line O-O of FIG. 1N; and FIG. 1P is a simplified partial cross-sectional view of the first microelectronic device structure 100 illustrating a different cross-section than that illustrated in FIG. 1L and illustrates the cross-section of the first microelectronic device structure 100 taken through section line P-P of FIG. 1N. FIG. 1Q is a simplified partial top-down view of the first microelectronic device structure 100. FIG. 1R is a simplified partial perspective view of the first microelectronic device structure 100.

With reference to FIG. 1N, recesses may be formed through the sixth insulative material 188, the fifth insulative material 180, and the portions of the conductive material 185 of the preliminary global digit lines 187 (FIG. 1M) to form global digit lines 108 including first global digit lines 108A and the second global digit lines 108B each individually in electrical communication with the global digit line contact structures 186 (e.g., the first global digit line contact structures 186A and the second global digit line contact structures 186B). In some embodiments, each first global digit line 108A is individually in electrical communication with multiple of the first global digit line contact structures 186A and the second global digit line contact structures 186B. In addition, each second global digit line 108B is individually in electrical communication with multiple of the first global digit line contact structures 186A and the second global digit line contact structures 186B.

The recesses may electrically isolate portions of the conductive material 185 of the preliminary global digit lines 187 (FIG. 1M) from one another to form the first global digit lines 108A electrically isolated from the second global digit lines 108B. In some embodiments, after forming the recesses and forming the first global digit lines 108A and the second global digit lines 108B, the recesses may be filled with a seventh insulative material 190 (FIG. 1N). In some embodiments, the seventh insulative material 190 vertically overlies (e.g., in the Z-direction) the first global digit lines 108A and the second global digit lines 108B.

The first global digit lines 108A and the second global digit lines 108B may collectively be referred to herein as “global digit lines.” The first global digit line 108A may be referred to herein as “through global digit lines.” The second global digit lines 108B may be referred to herein as “reference global digit lines.”

With reference to FIG. 1N through FIG. 1P and FIG. 1R, in some embodiments, some of the first global digit lines 108A are in electrical communication with the first global digit line contact structures 186A (FIG. 1N, FIG. 1P, FIG. 1R) and may be referred to as “high first global digit lines;” and other first global digit lines 108A are in electrical communication with the second global digit line contact structures 186B (FIG. 1N, FIG. 1Q, FIG. 1R) and may be referred to as “low first global digit lines.” In addition, some of the second global digit lines 108B are in electrical communication with the first global digit line contact structures 186A (FIG. 1N, FIG. 1P, FIG. 1R) and may be referred to as “high second global digit lines;” and other second global digit lines 108B are in electrical communication with the second global digit line contact structures 186B (FIG. 1N, FIG. 1Q, FIG. 1R) and may be referred to as “low second global digit lines.” In some embodiments, about one half of the first global digit lines 108A are in electrical communication with the first global digit line contact structures 186A are comprise the high first global digit lines and the other about one half of the first global digit lines 108A are in electrical communication with the second global digit line contact structures 186B are comprise low first global digit lines. In some embodiments, about one half of the second global digit lines 108B are in electrical communication with the first global digit line contact structures 186A are comprise the high first global digit lines and the other about one half of the second global digit lines 108B are in electrical communication with the second global digit line contact structures 186B are comprise low first global digit lines.

With reference FIG. 1Q, in some embodiments, every other one of the global digit lines 108 in a horizontal direction (e.g., in the Y-direction) is a first global digit line 108A and the other of the global digit lines 108 is a second global digit line 108B.

With reference to FIG. 1N, in some embodiments, every other one of the global digit lines 108 is in electrical communication with the first global digit line contact structures 186A and the other of the global digit lines 108 are in electrical communication with the second global digit line contact structures 186B. In some embodiments, horizontally neighboring (e.g., in the Y-direction) global digit lines 108 in electrical communication with the first global digit line contact structures 186A are spaced from one another by a horizontally intervening (e.g., in the X-direction) global digit line 108 in electrical communication with the second global digit line contact structures 186B. In addition, horizontally neighboring (e.g., in the Y-direction) global digit lines 108 in electrical communication with the second global digit line contact structures 186B are spaced from one another by a horizontally intervening (e.g., in the X-direction) global digit line 108 in electrical communication with the first global digit line contact structures 186A.

The first global digit lines 108A, the first global digit line contact structures 186A, the second global digit lines 108B, and the second global digit line contact structures 186B may individually be formed of and include the conductive material 185. In some embodiments, the first global digit lines 108A, the first global digit line contact structures 186A, the second global digit lines 108B, and the second global digit line contact structures 186B individually comprise titanium nitride. In other embodiments, the first global digit lines 108A, the first global digit line contact structures 186A, the second global digit lines 108B, and the second global digit line contact structures 186B individually comprise tungsten. In additional embodiments, the first global digit lines 108A, the first global digit line contact structures 186A, the second global digit lines 108B, and the second global digit line contact structures 186B individually comprise copper.

With continued reference to FIG. 1N, in some embodiments, a dimension D₄ (e.g., a width) of the first global digit lines 108A and the second global digit lines 108B may be greater than the dimension D₃ (FIG. 1J) of the contact openings 184 (FIG. 1J) and the corresponding dimension of the global digit line contact structures 186. In some embodiments, the dimension D₄ is within a range of from about 20 nm to about 50 nm, such as from about 20 nm to about 30 nm, from about 30 nm to about 40 nm, or from about 40 nm to about 60 nm. In some embodiments, the dimension D₄ is about 30 nm.

In some embodiments a pitch P₂ between horizontally neighboring (e.g., in the X-direction) global digit lines 108, such as between a first global digit line 108A and a horizontally neighboring (e.g., in the X-direction) second global digit line 108B is within a range of from about 80 nm to about 140 nm, such as from about 80 nm to about 100 nm, from about 100 nm to about 120 nm, or from about 120 nm to about 140 nm. In some embodiments, the pitch P₂ is from about 90 nm to about 120 nm.

In some embodiments, a vertical distance D₅ (e.g., in the Z-direction) between the first global digit lines 108A and the second global digit lines 108B is within a range of from about 50 nm to about 250 nm, such as from about 50 nm to about 100 nm, from about 100 nm to about 150 nm, from about 150 nm to about 200 nm, or from about 200 nm to about 250 nm. In some embodiments, the vertical distance D₅ is within a range of from about 100 nm to about 200 nm.

With reference to FIG. 1N through FIG. 1P, the seventh insulative material 190 may be formed within the recesses and vertically over (e.g., in the Z-direction) surfaces of the global digit lines 108. The seventh insulative material 190 may be formed of and include insulative material, such as one or more of the materials described above with reference to the first insulative material 112. In some embodiments, the seventh insulative material 190 is formed of and includes silicon dioxide.

With reference to FIG. 1O and FIG. 1P, in some embodiments, the multiplexers 166 facilitate selective provision of a voltage from a conductive pillar structure 160 to which it is electrically connected (by means of the global digit line contact structures 186) to selectively provide the voltage of the conductive pillar structure 160 to the global digit line 108 coupled to the global digit line contact structure 186 through the multiplexer 166. In other words, the global digit lines 108 are configured to be selectively electrically connected to the conductive pillar structures 160 by means of the multiplexers 166. Accordingly, the global digit lines 108 are configured to be selectively electrically connected to conductive pillar structures 160 vertically extending (e.g., in the Z-direction) through a respective vertical stack of memory cells 120 by applying a voltage to the multiplexer 166 electrically connecting the global digit line 108 to the particular conductive pillar structure 160 by means of the global digit line contact structures 162 and the isolated conductive structures 164 between the global digit line 108 and the multiplexer 166 associated with the particular conductive pillar structure 160. The multiplexers 166 may be driven by a multiplexer driver and/or a multiplexer control logic device operably coupled to the conductive structure 132 to which the multiplexer 166 is coupled (e.g., the conductive structure 132 vertically above (e.g., in the Z-direction) the multiplexer 166).

Each global digit line 108 may be configured to be selectively coupled to more than one of the conductive pillar structures 160 by means of the multiplexers 166 coupled to each of the conductive pillar structures 160. In some embodiments, each global digit line 108 is configured to selectively be in electrical communication with eight (4) of the conductive pillar structures 160, each one of which is associated with a different vertical stack structure 135. In other embodiments, each of the global digit lines 108 is configured to selectively be in electrical communication with four (8) of the conductive pillar structures 160 or sixteen (16) of the conductive pillar structures 160. One of the multiplexers 166 may be located between (e.g., horizontally between) a conductive pillar structure 160 and a horizontally neighboring conductive structure 164 that is, in turn, in electrical communication with a global digit line 108 by means of a global digit line contact structures 162. Accordingly, in some embodiments, the multiplexers 166 are individually configured to receive a signal (e.g., a select signal) from a multiplexer controller region and provide the signal to a bit line (e.g., conductive pillar structures 160 (FIG. 1L)) to selectively access desired memory cells within the array region 101 for effectuating one or more control operations of the memory cells 120.

Accordingly, the global digit lines 108 are configured to be selectively electrically connected to each conductive pillar structure 160 vertically extending (e.g., in the Z-direction) through a vertical stack of memory cells 120 by applying a voltage to the multiplexer 166 electrically connecting the global digit line 108 to the particular conductive pillar structure 160 by means of the global digit line contact structure 162 and the isolated conductive structures 164 between the global digit line 108 and the multiplexer 166 associated with the particular conductive pillar structure.

FIG. 2A and FIG. 2B are simplified partial cross-sectional views illustrating a microelectronic device 200 formed from the first microelectronic device structure 100 and a second microelectronic device structure 250 after attaching the second microelectronic device structure 250 to the first microelectronic device structure 100. FIG. 2A is a simplified cross-sectional view of the microelectronic device 200 and illustrates the same cross-sectional view of the first microelectronic device structure 100 illustrated in FIG. 1O. FIG. 2B is a simplified cross-sectional view of the microelectronic device 200 and illustrates the same cross-sectional view of the first microelectronic device structure 100 illustrated in FIG. 1P.

By way of non-limiting example, the second microelectronic device structure 250 may be attached to the first microelectronic device structure 100 by oxide-to-oxide bonding. In some such embodiments, an oxide material of the second microelectronic device structure 250 is brought into contact with an oxide material of the first microelectronic device structure 100 and the first microelectronic device structure 100 and the second microelectronic device structure 250 are exposed to annealing conditions to form bonds (e.g., oxide-to-oxide bonds) between the oxide material of the first microelectronic device structure 100 and the oxide material of the second microelectronic device structure 250.

The second microelectronic device structure 250 may include control logic devices (e.g., CMOS devices) and circuitry configured for effectuating control operations for the memory cells 120. By way of non-limiting example, the second microelectronic device structure 250 may include one or more sub word line driver regions, one or more socket regions, and one or more additional CMOS regions including one or more of (e.g., all of) one or more sense amplifier devices (e.g., equalization (EQ) amplifiers, isolation (ISO) amplifiers, NMOS sense amplifiers (NSAs), PMOS sense amplifiers (PSAs)), column decoders, multiplexer control logic devices, sense amplifier drivers, main word line driver devices, row decoder devices, and row select devices.

With reference to FIG. 2A and FIG. 2B, the second microelectronic device structure 250 may include one or more sense amplifier device regions 202 vertically overlying (e.g., in the Z-direction) and within horizontal boundaries of the vertical stacks of memory cells 120. The sense amplifier device regions 202 may include transistor structures in electrical communication with the global digit lines 108 by means of first conductive interconnect structures 204. In some embodiments, the sense amplifier device regions 202 include sense amplifier devices (e.g., equalization (EQ) amplifiers, isolation (ISO) amplifiers, NMOS sense amplifiers (NSAs), PMOS sense amplifiers (PSAs)).

With reference to FIG. 2C, the second microelectronic device structure 250 may include one or more sub word line driver regions 206 vertically overlying (e.g., in the Z-direction) and within horizontal boundaries of the staircase structures 174, such as vertically overlying the first conductive contact structures 176 and the first pad structures 178. The sub word line driver regions 206 may include transistor structures in electrical communication with the conductive structures 132 by means of second conductive interconnect structures 208 that are in electrical communication with the first pad structures 178.

Each of the first conductive interconnect structures 204 and the second conductive interconnect structures 208 are individually formed of and include conductive material, such as one or more of the conductive materials described above with reference to the first conductive interconnect structures 192. In some embodiments, the first conductive interconnect structures 204 and the second conductive interconnect structures 208 individually comprise tungsten. In other embodiments, the first conductive interconnect structures 204 and the second conductive interconnect structures 208 individually comprise copper.

Thus, in accordance with some embodiments, a microelectronic device comprises vertical stacks of memory cells. Each vertical stack of memory cells comprises a vertical stack of access devices, a vertical stack of capacitors horizontally neighboring the vertical stack of access devices, and a conductive pillar structure in electrical communication with the vertical stack of access devices. The microelectronic device further comprises first global digit lines vertically neighboring the vertical stacks of memory cells, and second global digit lines horizontally interleaved with the first global digit lines in a horizontal direction, the second global digit lines vertically spaced from the vertical stacks of memory cells a greater distance than the first global digit lines.

Furthermore, in accordance with additional embodiments of the disclosure, a memory device comprises vertical stacks of dynamic random access memory (DRAM) cells, each of the DRAM cells comprising a storage device horizontally neighboring an access device, conductive pillar structures vertically extending along the vertical stacks of DRAM cells, each of the conductive pillar structures in electrical communication with access devices of the vertical stacks of DRAM cells, and global digit lines vertically spaced from the vertical stacks of DRAM cells and horizontally spaced from one another in a horizontal direction, at least two of the global digit lines horizontally neighboring one another spaced a different vertical distance from the vertical stacks of DRAM cells than one another.

Moreover, in accordance with some embodiments of the disclosure, a method of forming a microelectronic device comprises forming vertical stacks of memory cells, each of the vertical stacks of memory cells comprising a vertical stack of access devices horizontally neighboring a vertical stack of capacitor structures, forming multiplexers vertically overlying the vertical stacks of memory cells, forming first openings through an insulative material overlying a first group of the multiplexers, forming second openings through the insulative material overlying a second group of the multiplexers, forming trenches within the insulative material, the first group of the multiplexers and the first openings located within horizontal boundaries of the trenches, and the second group of the multiplexers and the second openings located outside of the horizontal boundaries of the trenches, forming conductive material within the trenches and the first openings to form first global digit lines, and forming conductive material within the second openings and over surfaces of the insulative material to form second global digit lines vertically spaced from the multiplexers by a greater vertical distance than the first global digit lines.

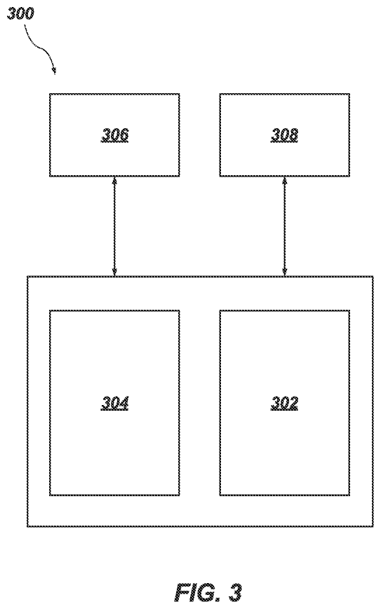

Structures, assemblies, and devices in accordance with embodiments of the disclosure may be included in electronic systems of the disclosure. For example, FIG. 3 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may comprise, for example, an embodiment of one or more of a microelectronic device structure, a microelectronic device structure assembly, a relatively larger microelectronic device structure assembly, and a microelectronic device previously described herein with reference to FIG. 1A through FIG. 2B. The electronic system 300 may further include at least one electronic signal processor device 304 (often referred to as a “microprocessor”). The electronic signal processor device 304 may, optionally, include an embodiment of one or more of a microelectronic device structure, a microelectronic device structure assembly, a relatively larger microelectronic device structure assembly, and a microelectronic device previously described herein with reference to FIG. 1A through FIG. 2B. While the memory device 302 and the electronic signal processor device 304 are depicted as two (2) separate devices in FIG. 3, in additional embodiments, a single (e.g., only one) memory/processor device having the functionalities of the memory device 302 and the electronic signal processor device 304 is included in the electronic system 300. In such embodiments, the memory/processor device may include one or more of a microelectronic device structure, a microelectronic device structure assembly, a relatively larger microelectronic device structure assembly, and a microelectronic device previously described herein with reference to FIG. 1A through FIG. 2B. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, one or more of a monitor, a display, a printer, an audio output jack, and a speaker. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

Thus, in accordance with embodiments of the disclosure, an electronic system comprises an input device, an output device, a processor device operably coupled to the input device and the output device, and a memory device operably coupled to the processor device. The memory device comprises vertical stacks of access devices, vertical stacks of capacitor structures horizontally neighboring the vertical stacks of access devices, conductive pillar structures individually vertically extending proximate to and in electrical communication with one of the vertical stacks of access devices, multiplexers vertically overlying the vertical stacks of capacitor structures, first global digit lines vertically overlying the multiplexers, the first global digit lines in electrical communication with some of the multiplexers, and second global digit lines vertically spaced from the first global digit lines and in electrical communication with others of the multiplexers.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
vertical stacks of memory cells, each vertical stack of memory cells comprising:
a vertical stack of access devices;
a vertical stack of capacitors horizontally neighboring the vertical stack of access devices; and
a conductive pillar structure in electrical communication with the vertical stack of access devices;
first global digit lines vertically neighboring the vertical stacks of memory cells; and
second global digit lines horizontally interleaved with the first global digit lines in a horizontal direction, the second global digit lines vertically spaced from the vertical stacks of memory cells a greater distance than the first global digit lines.

2. The microelectronic device of claim 1, wherein each one of the second global digit lines individually horizontally neighbors at least one of the first global digit lines.

3. The microelectronic device of claim 1, wherein a vertical distance between the first global digit lines and the second global digit lines is within a range of from about 100 nm to about 200 nm.

4. The microelectronic device of claim 1, wherein the second global digit lines are in electrical communication with second global digit line contact structures having a larger vertical dimension than first global digit line contact structures in electrical communication with the first global digit lines.

5. The microelectronic device of claim 1, wherein a distance between the conductive pillar structures in the horizontal direction is within a range of from about 50 nm to about 150 nm.

6. The microelectronic device of claim 1, wherein a vertical distance between an uppermost surface of the conductive pillar structures of the vertical stacks of memory cells and the second global digit lines is about two times a vertical distance between the uppermost surface of the conductive pillar structures and the first global digit lines.

7. The microelectronic device of claim 1, wherein the first global digit lines and the second global digit lines are individually in electrical communication with a sense amplifier.

8. The microelectronic device of claim 1, wherein the first global digit lines and the second global digit lines individually have a dimension in the horizontal direction is within a range of from about 20 nm to about 50 nm.

9. The microelectronic device of claim 1, wherein a distance between one of the first global digit lines and one of the second global digit lines horizontally neighboring the one of the first global digit lines in the horizontal direction is within a range of from about 80 nm to about 120 nm.

10. The microelectronic device of claim 1, further comprising a stack structure comprising vertically spaced conductive structures, at least some of the vertically spaced conductive structures are individually in electrical communication with a memory cell of the vertical stack of memory cells and comprise a gate of an access device of the vertical stack of access devices.

11. The microelectronic device of claim 1, wherein the first global digit lines are individually in electrical communication with four conductive pillar structures.

12. A memory device, comprising:
vertical stacks of dynamic random access memory (DRAM) cells, each of the DRAM cells comprising a storage device horizontally neighboring an access device;
conductive pillar structures vertically extending along the vertical stacks of DRAM cells, each of the conductive pillar structures in electrical communication with access devices of one of the vertical stacks of DRAM cells; and
global digit lines vertically spaced from the vertical stacks of DRAM cells and horizontally spaced from one another in a horizontal direction, at least two of the global digit lines horizontally neighboring one another spaced a different vertical distance from the vertical stacks of DRAM cells than one another.

13. The memory device of claim 12, wherein every other one of the global digit lines is located a same vertical distance from the vertical stacks of DRAM cells.

14. The memory device of claim 12, further comprising conductive structures horizontally extending in the horizontal direction and individually in electrical communication with the DRAM cells of the vertical stacks of DRAM cells.

15. The memory device of claim 12, wherein one half of the global digit lines are located a first vertical distance from the vertical stacks of DRAM cells and an additional one half of the global digit lines are located a second, greater vertical distance from the vertical stacks of DRAM cells.

16. The memory device of claim 12, wherein each of the global digit lines is in electrical communication with multiple conductive pillar structures.

17. The memory device of claim 16, further comprising multiple multiplexers, each of the multiplexers intervening between one of the global digit lines and a conductive pillar structure.

18. The memory device of claim 17, further comprising global digit line contacts, each of the global digit line contacts individually in electrical communication with a multiplexer and one of the global digit lines.

19. A method of forming a microelectronic device, the method comprising:
forming vertical stacks of memory cells, each of the vertical stacks of memory cells comprising a vertical stack of access devices horizontally neighboring a vertical stack of capacitor structures;
forming multiplexers vertically overlying the vertical stacks of memory cells;
forming first openings through an insulative material overlying a first group of the multiplexers;
forming second openings through the insulative material overlying a second group of the multiplexers;
forming trenches within the insulative material, the first group of the multiplexers and the first openings located within horizontal boundaries of the trenches, and the second group of the multiplexers and the second openings located outside of the horizontal boundaries of the trenches;
forming conductive material within the trenches and the first openings to form first global digit lines; and
forming conductive material within the second openings and over surfaces of the insulative material to form second global digit lines vertically spaced from the multiplexers by a greater vertical distance than the first global digit lines.

20. The method of claim 19, further comprising forming a resist material within the trenches, wherein forming the first openings comprises forming the first openings through the resist material and the insulative material.

21. The method of claim 19, wherein forming conductive material within the second openings comprises forming global digit line contact structures having a vertical dimension greater than a vertical dimension of additional global digit line contact structures within the first openings.

22. The method of claim 19, further comprising removing portions of the conductive material to electrically isolate the first global digit lines and the second global digit lines.

23. The method of claim 19, wherein forming second global digit lines comprises forming the second global digit lines to be horizontally interleaved with the first global digit lines.

24. An electronic system, comprising:
an input device;
an output device;
a processor device operably coupled to the input device and the output device; and
a memory device operably coupled to the processor device and comprising:
vertical stacks of access devices;
vertical stacks of capacitor structures horizontally neighboring the vertical stacks of access devices;
conductive pillar structures individually vertically extending proximate to and in electrical communication with one of the vertical stacks of access devices;
multiplexers vertically overlying the vertical stacks of capacitor structures;
first global digit lines vertically overlying the multiplexers, the first global digit lines in electrical communication with some of the multiplexers; and
second global digit lines vertically spaced from the first global digit lines and in electrical communication with others of the multiplexers.

25. The electronic system of claim 24, wherein each of the first global digit lines is horizontally spaced from a horizontally neighboring one of the first global digit lines by one of the second global digit lines.

26. The electronic system of claim 24, wherein the first global digit lines are in electrical communication with first global digit line contact structures having a smaller vertical dimension than second global digit line contact structures in electrical communication with the second global digit lines.

27. The electronic system of claim 24, wherein the multiplexers individually comprise a first electrode material in electrical communication with a second electrode material.

28. The electronic system of claim 24, further comprising sense amplifiers vertically overlying the first global digit lines and the second global digit lines, the sense amplifiers in electrical communication with the first global digit lines and the second global digit lines.

29. The electronic system of claim 28, wherein the second global digit lines are vertically closer to the sense amplifiers than the first global digit lines.
